(19) United States
(12) Patent Application Publication
(10) Pub. No.: US 2026/0215138 A1
(43) Pub. Date: Jul. 23, 2026

(54) DISPLAY PANEL AND DISPLAY APPARATUS COMPRISING THE SAME

(71) Applicant: LG Display Co., Ltd., Seoul (KR)

(72) Inventors: Minki Kim, Anyang-si (KR); Kisoub Yang, Paju-si (KR); Hakmin Lee, Paju-si (KR); Beomgon Jo, Goyang-si (KR)

(21) Appl. No.: 19/379,567

(22) Filed: Nov. 4, 2025

(30) Foreign Application Priority Data
Jan. 22, 2025 (KR) 10-2025-0009448

(51) Int. Cl. H10K 59/80

(52) U.S. Cl. CPC H10K 59/879; H10K 59/80515; H10K 59/80518; H10K 59/8792

(57) ABSTRACT

A display panel includes a light-reflecting layer arranged on a light-emitting element layer, where at least a portion of light emitted upward from the light-emitting element layer can be reflected back toward a reflective electrode layer that is positioned under the light-emitting element layer.

### CROSS REFERENCE TO RELATED APPLICATION

Pursuant to 35 U.S.C. § 119(a), this application claims the benefit of an earlier filing date and right of priority to Korean Patent Application No. 10-2025-0009448, filed Jan. 22, 2025, the entire contents of which are incorporated herein for all purposes by this reference.

### TECHNICAL FIELD

The present disclosure generally relates to a display panel and a display apparatus including the display panel.

### BACKGROUND

Display devices are implemented in various forms, such as televisions, monitors, smartphones, tablet PCs, laptops, wearable devices, etc.

Among display devices that display various pieces of information as images, an organic light-emitting diode (OLED) display device is a self-luminous element that emits light by itself and has the advantages of a fast response time, high luminous efficiency and brightness, a large viewing angle, and excellent contrast ratio and color reproducibility.

Recently, as users'demands for high-quality images have increased, development of high-resolution display devices is actively being conducted.

### SUMMARY

According to an implementation of the present disclosure, there is provided a display panel including a substrate including a plurality of sub-pixels, a reflective electrode layer disposed on the substrate in each of the sub-pixels, a first electrode disposed on the reflective electrode layer, a light-emitting element layer disposed on the first electrode, a second electrode disposed on the light-emitting element layer, and one or more pattern layers disposed on the second electrode to overlap each of the sub-pixels, wherein each of the pattern layers includes a light-reflecting layer and a light-absorbing layer sequentially stacked.

A plurality of pattern layers may be disposed on each of the sub-pixels, and the plurality of pattern layers may be disposed to be spaced apart from each other.

The plurality of pattern layers may be disposed in a form of a matrix in a plan view.

The plurality of pattern layers may be arranged in a plan view as a plurality of slits each extending along a first direction and spaced apart from each other in a second direction.

The pattern layer may be formed along the edges of the reflective electrode layer.

The light-reflecting layer may include silver (Ag) or aluminum (Al).

The light-absorbing layer may include a black matrix.

The reflective electrode layer may have a thickness different from that in each of the other sub-pixels.

The reflective electrode layer may include a lower reflective layer, an insulating layer disposed on the lower reflective layer, and an upper reflective layer disposed on the insulating layer, and the lower reflective layer may be thicker than the upper reflective layer.

The insulating layer may have a different thickness in each of the sub-pixels.

In addition, according to another implementation of the present disclosure, there is provided a display panel including a substrate including a plurality of sub-pixels, a reflective electrode layer disposed on the substrate in each of the sub-pixels, a light-emitting element layer disposed on the reflective electrode layer to correspond to the plurality of sub-pixels, and one or more light-reflecting layers disposed on the light-emitting element layer of each of the sub-pixels to cover a portion of the reflective electrode layer, wherein some light emitted from the light-emitting element layer is reflected from the light-reflecting layer to the reflective electrode layer, then re-reflected from the reflective electrode layer, and emitted to the outside.

Some of the re-reflected light re-reflected from the reflective electrode layer may be reflected from the light-reflecting layer back to the reflective electrode layer, then re-reflected from the reflective electrode layer, and emitted to the outside.

A light-absorbing layer that absorbs external light may be further disposed on the light-reflecting layer.

The light-absorbing layer may be disposed in contact with the light-reflecting layer so as to have the same pattern as the light-reflecting layer so that the light-absorbing layer and the light-reflecting layer form a pattern layer.

The pattern layer may be provided as a plurality of pattern layers, and the plurality of pattern layers may be disposed to be spaced a predetermined distance from each other so that a light-transmissive portion is formed between adjacent pattern layers.

The reflective electrode layer may include a lower reflective layer, an insulating layer disposed on the lower reflective layer, and an upper reflective layer disposed on the insulating layer, and the insulating layer may have a different thickness in each of the sub-pixels.

The lower reflective layer may be thicker than the upper reflective layer.

In addition, according to an implementation of the present disclosure, there is provided a display apparatus including the display panel, and a case part that is configured to house one or more display panels.

The display panel may include a first display panel and a second display panel that are disposed to be spaced apart from each other, and the case part further houses a left-eye lens disposed between the first display panel and a left eye of a user, and a right-eye lens disposed between the second display panel and a right eye of the user.

### BRIEF DESCRIPTION OF THE DRAWINGS

FIG. 1 is a plan view of an example of a display apparatus according to an implementation of the present disclosure.

FIG. 2 is a plan view showing an example of a unit pixel according to an implementation of the present disclosure.

FIG. 3 is a cross-sectional view along line I-I′ in FIG. 2.

FIGS. 4 to 6 are cross-sectional views of an example of a reflective electrode layer disposed in each sub-pixel.

FIGS. 7 to 10 are plan views showing an example of patterns of pattern layers according to various implementations.

FIG. 11 is a view showing an example of a light distribution of a display panel without a pattern layer disposed, and FIG. 12 is a view showing an example of a light distribution of a display panel with the pattern layer disposed.

FIGS. 13 to 15 are views showing an example of an emission spectrum of each sub-pixel before the microcavity effect is applied.

FIGS. 16 and 17 are graphs showing an example of light absorptance and reflectance according to a change in thickness of an upper reflective layer of a reflective electrode layer.

FIGS. 18 and 19 are graphs showing an example of light absorptance and reflectance according to a change in thickness of an insulating layer of the reflective electrode layer.

FIGS. 20 and 21 are graphs showing an example of light absorptance and reflectance according to a change in thickness of a lower reflective layer of the reflective electrode layer.

FIGS. 22 and 23 are graphs showing an example of the light absorptance according to the change in thickness of the upper electrode layer of the reflective electrode layer and the light absorptance according to the change in thickness of the insulating layer of the reflective electrode layer, respectively.

FIGS. 24 and 25 are graphs showing an example of a light reflectance and absorptance by a reflective electrode layer in a first sub-pixel, respectively.

FIGS. 26 and 27 are graphs showing an example of a light reflectance and absorptance by a reflective electrode layer in a second sub-pixel, respectively.

FIGS. 28 and 29 are graphs showing an example of a light reflectance and absorptance by a reflective electrode layer in a third sub-pixel, respectively.

FIGS. 30 to 32 are views showing an example of a final emission spectrum of each sub-pixel.

FIGS. 33 to 35 show an example of a head-mounted display apparatus including the display apparatus according to one implementation of the present disclosure.

### DETAILED DESCRIPTION

Head-mounted display apparatuses can include an organic light-emitting diode (OLED) display device. A head-mounted display apparatus is an apparatus that is worn on a user's head to position a display screen in front of the user's eyes. The head-mounted display apparatus can be used in various applications such as virtual reality (VR), augmented reality (AR), mixed reality (MR), etc. and can play an important role in providing users with an immersive experience.

For example, VR has an advantage of providing excellent user immersion, allowing even a 1-inch image to appear as a 60-inch image. To this end, a small display apparatus with ultra-high resolution is applied to the head-mounted display apparatus. However, a small display apparatus with ultra-high resolution often faces a problem in that it is difficult to implement a light-emitting element layer using a fine metal mask due to a dense pixel spacing.

The head-mounted display apparatus can be formed using OLED on silicon (OLEDoS) technology, which is a technology of forming an OLED on a silicon substrate. Generally, an OLEDoS can manufacture a display apparatus with higher resolution and higher density using a silicon wafer instead of a glass or plastic substrate.

Applying a microcavity structure to a head-mounted display apparatus with such an OLEDoS structure can help increase the efficiency of the display apparatus and improve color representation. The microcavity structure is a technology of amplifying light of a specific wavelength in an OLED display apparatus to increase color reproducibility. The microcavity structure can be composed of a thin dielectric layer and a reflective layer and can resonate and strengthen light of a specific wavelength to amplify the luminous efficiency in the OLED structure.

To implement the small display apparatus with ultra-high resolution, there is a need for a semiconductor process using less expensive equipment.

In addition, for display apparatuses using a microcavity structure, when the microcavity effect is rendered less effective due to increased amounts of light emitted directly to the outside of the display panel, a problem of reduced color sensation can occur.

In addition, when a polarizing plate is included in the display panel to reduce the reflectance of external light, a problem of reduced brightness can occur due to the polarizing plate.

Accordingly, implementations of the present disclosure can provide a display apparatus that can configure dense pixels to implement ultra-high resolution without using expensive equipment through various experiments.

Implementations of the present disclosure can provide a display panel and a display apparatus in which color sensation can be improved.

In addition, implementations of the present disclosure can provide a display panel and a display apparatus in which a reduction in brightness can be mitigated by omitting a polarizing plate.

In addition, implementations of the present disclosure can provide a display panel and a display apparatus in which a process can be simplified and a need for expensive equipment can be eliminated by omitting a color filter.

In addition, implementations of the present disclosure can provide a display panel and a display apparatus in which optical efficiency of a light-emitting element can be increased by including a light-emitting element layer that emits white light.

In addition, implementations of the present disclosure can provide a display panel and a display apparatus that heightens the immersive experience of a user wearing a head-mounted display apparatus.

Implementations disclosed herein can provide various technical benefits, some examples of which are described below.

According to some implementations of the present disclosure, by arranging a light-reflecting layer on a light-emitting element layer, at least a portion of light emitted upward from the light-emitting element layer can be reflected to the reflective electrode layer positioned thereunder. Accordingly, among the light emitted from the light-emitting element, light that is emitted directly to the outside of the display panel without passing through the reflective electrode layer can be reduced, thereby improving the color sensation of the display panel.

In addition, according to some implementations of the present disclosure, a light-absorbing layer having a predetermined pattern can be disposed on the light-emitting element layer in each sub-pixel, thereby replacing the role of the polarizing plate. Accordingly, the light-absorbing layer can effectively absorb external light, thereby reducing the reflectance of the display panel and preventing a reduction in brightness that can occur due to the arrangement of the polarizing plate.

In addition, according to some implementations of the present disclosure, a multilayered reflective electrode layer including a lower reflective layer, an insulating layer, and an upper reflective layer can be disposed in each sub-pixel, thereby selectively emitting light within a specific wavelength range.

In addition, according to some implementations of the present disclosure, the thickness of the upper reflective layer can be adjusted to absorb light outside the target wavelength range, and the thickness of the insulating layer can be adjusted to adjust the distance between the lower reflective layer and the upper reflective layer to adjust the wavelength range to be absorbed. Accordingly, since the light of the target color can be strongly emitted, color purity and color reproducibility can be improved, thereby improving user immersion.

In addition, according to some implementations of the present disclosure, since the color filter requiring expensive equipment can be omitted in the small display apparatus with ultra-high resolution, the cost of the finished product can be reduced. In addition, since the process operations can be simplified by omitting the color filter, process optimization can be implemented, and production energy can be reduced.

In addition, according to some implementations of the present disclosure, since the color filter can be omitted, light loss through the color filter can be prevented, thereby increasing optical efficiency.

Accordingly, according to some implementations of the present disclosure, since high color reproducibility and high brightness of the display panel and the display apparatus can be implemented, the power consumption of the display panel and the display apparatus can be reduced, thereby implementing the low-power display panel and display apparatus.

Specific technical effects together with the above-described technical effects are described together with a description of the following detailed matters for carrying out implementations of the disclosure.

Objects of implementations of the present disclosure are not limited to the above-described objects, and other objects that are not mentioned will be able to be clearly understood by those skilled in the art from the following description.

Advantages and features of the present disclosure and methods for achieving them will become clear by referencing implementations described below in detail in conjunction with the accompanying drawings. However, the present disclosure is not limited to the implementations disclosed below but can be implemented in various different forms, these implementations are merely provided to make the disclosure of the present disclosure complete and fully inform those skilled in the art to which the present disclosure pertains of the scope of the present disclosure, and the present disclosure is only defined by the scope of the appended claims.

Since shapes, sizes, ratios, angles, numbers, etc. disclosed in the drawings for describing the implementations of the present disclosure are illustrative, the present disclosure is not limited to the shown items. The same reference number denotes the same components throughout the disclosure. In addition, in describing the present disclosure, when it is determined that the detailed description of a related known technology may unnecessarily obscure the gist of the present disclosure, the detailed description thereof will be omitted. When “comprises,” “has,” “consists of,” and the like described in the present disclosure are used, other parts may be added unless “only” is used. When a component is expressed in a singular form, it includes a case in which the component is provided as a plurality of components unless specifically stated otherwise.

In construing a component, the component is construed as including a margin of error even when there is no separate explicit description.

When a positional relationship is described, for example, when the positional relationship between two parts is described using “on,” “above,” “under,” “next to,” etc., one or more other parts may be positioned between the two parts unless “immediately” or “directly” is used.

When the temporal relationship is described, for example, when the temporal relationship is described using the term “after,” “subsequently,” “then,” “before,” or the like, it may include a non-consecutive case unless the term “immediately” or “directly” is used.

Although terms such as first and second are used to describe various components, these components are not limited by these terms. The terms are only used to distinguish one component from another. Accordingly, a first component described below may be a second component within the technical idea of the present disclosure.

Features of various implementations of the present disclosure may be coupled or combined partially or entirely, various technological interworking and driving are made possible, and the implementations may be implemented independently of each other or implemented together in an associated relationship.

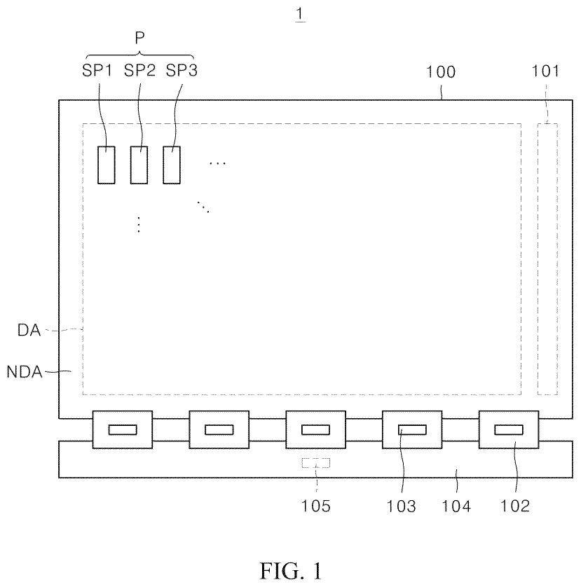

FIGS. 1 to 10 illustrate example implementations of a display panel and a display apparatus. The examples in which a display apparatus 1 is described below is an organic light-emitting diode display apparatus, but implementations of the present disclosure are not limited thereto.

The display apparatus 1 may include a first substrate 100 including a display area DA and a non-display area NDA surrounding the display area DA. The display apparatus 1 may include the first substrate 100, a source driving integrated circuit (IC) 103, a flexible film 102, a circuit board 104, and a timing controller 105.

The display area DA on the first substrate 100 may include a plurality of sub-pixels SP1, SP2, and SP3 each formed in one of areas defined by the intersection of a plurality of data lines extending in a first direction and a plurality of gate lines extending in a second direction intersecting the first direction. The first direction described in the present disclosure may be an X-axis direction, the second direction may be a Y-axis direction, and a Z-axis direction may be a direction perpendicular to the X-axis and the Y-axis. In addition, in the present disclosure, an implementation in which one pixel P is composed of a first sub-pixel SP1, a second sub-pixel SP2, and a third sub-pixel SP3 will be described, but the present disclosure is not limited thereto, and one pixel P may further include additional sub-pixels.

Each of the sub-pixels SP1, SP2, and SP3 may be implemented to emit light of the same color for each sub-pixel, such as white light, or implemented to emit light of a different color for each sub-pixel, such as red, green, or blue light. Hereinafter, an implementation in which the first sub-pixel SP1 implements red, the second sub-pixel SP2 implements green, and the third sub-pixel SP3 implements blue will be described. The plurality of sub-pixels SP1, SP2, and SP3 may be disposed in a form of a matrix arranged in a plurality of rows and columns.

A gate driver 101 positioned on one side or both sides of the display area DA may be disposed on the non-display area NDA on the first substrate 100. The gate driver 101 may be implemented in a gate-in-panel (GIP) manner. The gate driver 101 may generate gate signals to gate lines according to a gate control signal received from the timing controller 105.

The source driving IC 103 may receive digital video data and a source control signal from the timing controller 105. The source driving IC 103 may convert the digital video data into analog data voltages according to the source control signal and supply the analog data voltages to data lines. The source driving IC 103 may be manufactured as a driving chip in a chip-on-film (COF) or chip on plastic (COP) manner and mounted on a plurality of flexible films 102. The circuit board 104 may be attached to the plurality of flexible films 102. A plurality of circuits implemented as chips such as the timing controller 105 may be mounted on the circuit board 104.

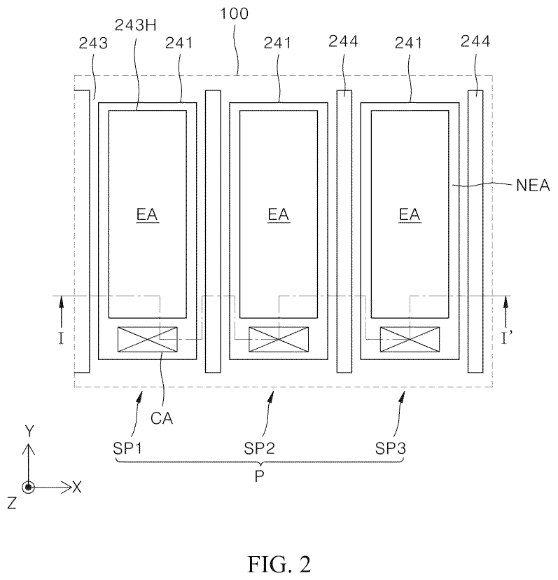

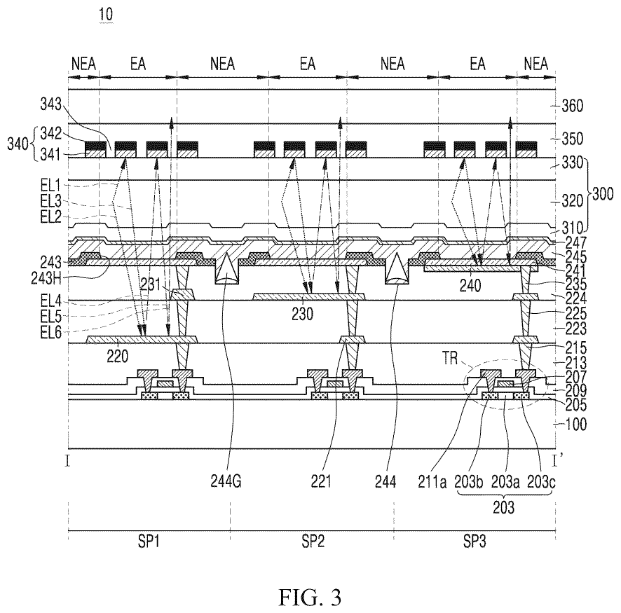

Referring to the examples of FIGS. 2 and 3, the plurality of sub-pixels SP1, SP2, and SP3 may be disposed in the display area of the first substrate 100 to form one pixel P. A plurality of light-emitting areas EA may be positioned corresponding one-to-one to the sub-pixels SP1, SP2, and SP3. A first light-emitting area EA may be positioned in the first sub-pixel SP1, a second light-emitting area EA may be positioned in the second sub-pixel SP2, and a third light-emitting area EA may be positioned in the third sub-pixel SP3.

Each of the plurality of light-emitting areas EA may be defined by a bank 243 including a bank hole 243H. The bank hole 243H may be an opening that exposes the light-emitting area EA. That is, areas that are exposed without being covered by the bank 243 may be the plurality of light-emitting areas EA. The first electrodes 241 may be disposed to be spaced apart from each other in the plurality of sub-pixels SP1, SP2, and SP3. A portion of the first electrode 241 exposed by the bank hole 243H of the bank 243 may be defined as a light-emitting area.

Trenches 244 extending in the second direction may be disposed in boundary areas between the plurality of sub-pixels SP1, SP2, and SP3. The trench 244 may be disposed between the first sub-pixel SP1 and the second sub-pixel SP2 adjacent to each other, between the second sub-pixel SP2 and the third sub-pixel SP3 adjacent to each other, and between the third sub-pixel SP3 and the first sub-pixel SP1 adjacent to each other. For example, the trench 244 may extend to be larger than a length of each of the plurality of light-emitting areas EA.

The first electrode 241 disposed on each of the plurality of sub-pixels SP1, SP2, and SP3 may be electrically connected to at least one transistor disposed on the first substrate 100 through each contact area CA. Hereinafter, the description thereof will be made with reference to FIG. 3.

The display apparatus according to one implementation of the present disclosure may be one of a top emission type or a bottom emission type depending on a direction in which light emitted from the light-emitting element layer is emitted. Hereinafter, the top emission type will be described as an example.

The first substrate 100 may be formed of glass or plastic such as polyimide, but is not limited thereto, and may be formed of a semiconductor material such as a silicon wafer. For example, the first substrate 100 may be a single-crystal silicon wafer formed by growing single-crystal silicon (Si) or a wafer formed of various semiconductor materials. Hereinafter, an OLED on Si wafer (OLEDoS) structure in which the light-emitting element layer 245 including an organic light-emitting diode is disposed on the first substrate 100 that is a silicon wafer will be described as an implementation, but is not limited thereto.

On the first substrate 100, a driving circuit including various signal lines, transistors, capacitors, etc. may be disposed in each of the sub-pixels SP1, SP2, and SP3. The signal lines may include a gate line, a data line, a power line, and a reference line, and the transistors may include a switching transistor and a driving transistor TR. For example, the switching transistor and the driving transistor may be formed on the first substrate 100 using a complementary metal oxide semiconductor (CMOS) process. In the implementations of the present disclosure, the driving transistor TR is shown for convenience of description.

The driving transistor TR may include a semiconductor layer 203, a gate insulating layer 205, a gate electrode 207, and source/drain electrodes 211a and 211b. The gate insulating layer 205 may be disposed between the semiconductor layer 203 and the gate electrode 207. A buffer layer, which is an insulating layer that reduces or prevents permeation of moisture or impurities may be further included between the first substrate 100 and the semiconductor layer 203.

The semiconductor layer 203 may be made of an oxide semiconductor or a silicon-based semiconductor material. For example, the semiconductor layer 203 may include a transparent oxide semiconductor material such as indium gallium-zinc-oxide (IGZO) or indium-zinc-oxide (IZO) or include a polysilicon semiconductor material. The semiconductor layer 203 may include a channel area 203a, and a source area 203b and a drain area 203c respectively positioned at both sides of the channel area 203a.

A gate electrode 207 overlapping the channel area 203a of the semiconductor layer 203 in a vertical direction may be disposed on the gate insulating layer 205. An interlayer insulating layer 209 may be disposed on the gate electrode 207. The source electrode 211a and the drain electrode 211b may be disposed on the interlayer insulating layer 209. The source electrode 211a and the drain electrode 211b may be connected to the source area 203b and the drain area 203c of the semiconductor layer 203 through contact holes formed in the interlayer insulating layer 209 and the gate insulating layer 205, respectively.

A first insulating layer 213 may be disposed on the interlayer insulating layer 209, the source electrode 211a, and the drain electrode 211b. The first insulating layer 213 may cover transistors including the driving transistors TR, various signal lines, capacitors, etc., which are disposed on the first substrate 100. A first reflective electrode layer 220 and a plurality of first contact electrodes 221 may be disposed on the first insulating layer 213. The first reflective electrode layer 220 may be disposed in the first sub-pixel SP1, and the plurality of first contact electrodes 221 may be disposed one-to-one in the second sub-pixel SP2 and the third sub-pixel SP3. The first reflective electrode layer 220 and the plurality of first contact electrodes 221 may be formed of the same material in the same layer. A plurality of first via 215 passing through the first insulating layer 213 may be disposed to be spaced apart from each other. One side of the first via 215 may be connected to each of the first reflective electrode layer 220 and the plurality of first contact electrodes 221, and the other side may be electrically connected to the driving transistor TR. For example, the plurality of first contact electrodes 221 may be connected to the drain electrode 211b of the driving transistor TR.

A second insulating layer 223 may be disposed on the first insulating layer 213, the first reflective electrode layer 220, and the plurality of first contact electrodes 221. A second reflective electrode layer 230 and a plurality of second contact electrodes 231 may be disposed on the second insulating layer 223. The second reflective electrode layer 230 may be disposed in the second sub-pixel SP2, and the plurality of second contact electrodes 231 may be disposed one-to-one in the first sub-pixel SP1 and the third sub-pixel SP3. The second reflective electrode layer 230 and the plurality of second contact electrodes 231 may be formed of the same material in the same layer. A plurality of second via 225 passing through the second insulating layer 223 may be disposed to be spaced apart from each other. One side of the second via 225 may be connected to each of the second reflective electrode layer 230 and the plurality of second contact electrodes 231, and the other side may be electrically connected to the first reflective electrode layer 220 and the plurality of first contact electrodes 221.

A third insulating layer 224 may be disposed on the second reflective electrode layer 230 and the second contact electrode 231. The first insulating layer 213, the second insulating layer 223, and the third insulating layer 224 may be formed of a single layer or multiple layers of an inorganic film such as silicon nitride, aluminum nitride, zirconium nitride, titanium nitride, hafnium nitride, tantalum nitride, silicon oxide, aluminum oxide, or titanium oxide, but are not limited thereto, and formed of a single layer or multiple layers of an organic film such as an acryl resin, an epoxy resin, a phenolic resin, a polyamide resin, a polyimide resin, etc. The third insulating layer 224 may serve to planarize a step occurring due to a lower circuit element including the driving transistor TR. The third insulating layer 224 may be referred to as a planarization layer.

The plurality of first electrodes 241 may be disposed on the third insulating layer 224 one-to-one in the plurality of sub-pixels SP1, SP2, and SP3. In the third sub-pixel SP3, the third reflective electrode layer 240 may be disposed in contact with a rear surface of the first electrode 241, but is not limited thereto. For example, an insulating layer may be further disposed on the third reflective electrode layer 240, and the plurality of first electrodes 241 may be disposed on the insulating layer. In this case, the third reflective electrode layer 240 and the first electrode 241 may be electrically connected through an additional via electrode. A plurality of third vias 235 passing through the third insulating layer 224 may be disposed to be spaced apart from each other. One side of the third via 235 may be connected to the first electrode 241 of each of the sub-pixels SP1, SP2, and SP3, and the other side may be electrically connected to each of the second reflective electrode layer 230 and the plurality of second contact electrodes 231. In the third sub-pixel SP3, the third reflective electrode layer 240 may be connected to the second contact electrode 231 through the third via 235, but is not limited thereto.

The first reflective electrode layer 220, the second reflective electrode layer 230, and the third reflective electrode layer 240 may include a metal material with high reflectance, such as silver (Ag), a silver alloy, aluminum (Al), or an aluminum alloy.

The first electrode 241 disposed on each of the sub-pixels SP1, SP2, and SP3 may include a transparent metal oxide such as ITO or IZO. Alternatively, the first electrode 241 may include a single-layer or multilayered structure including a reflective metal film made of silver (Ag), aluminum (Al), gold (Au), nickel (Ni), chromium (Cr), and compounds thereof. The first electrode 241 may also be referred to as a pixel electrode or an anode electrode.

The bank 243 may be disposed on the third insulating layer 224. The bank 243 serves to divide the sub-pixels SP1, SP2, and SP3. To this end, the bank 243 may be formed to cover an edge of the first electrode 241. In addition, the light-emitting area EA and the non-light-emitting area NEA may be distinguished through the bank hole 243H of the bank 243. Accordingly, the bank 243 can prevent light of different colors between adjacent sub-pixels from being mixed and output. The bank 243 may include an organic insulation film such as polyimide or an epoxy. In one example, the bank 243 may include one of a black resin, graphite, and black ink.

The trench 244 may be disposed in the bank 243 and the third insulating layer 224. For example, the trench 244 may have a concave shape including a bottom surface and two side surfaces extending from the bottom surface. The trenches 244 may pass through the banks 243 in the boundary areas between adjacent sub-pixels SP1, SP2, and SP3 and extend in a thickness direction of the third insulating layer 224. For example, the trench 244 may be disposed in the boundary area between the first sub-pixel SP1 and the second sub-pixel SP2 and the boundary area between the second sub-pixel SP2 and the third sub-pixel SP3. The trench 244 may be disposed in the non-light-emitting area NEA. In another example, the trench 244 may extend to the second insulating layer 223.

The light-emitting element layer 245 may be disposed on the first electrode 241. In one example, the light-emitting element layer 245 may include an organic material that emits white light. The light-emitting element layer 245 may include a multi-stack structure in which at least two stacks each including a hole transport layer (HTL), an emissive layer (EML), an electron transport layer (ETL), a hole blocking layer (HBL), a hole injecting layer (HIL), an electron blocking layer (EBL), and an electron injecting layer (EIL) are stacked. For example, when two or more stacks are stacked, a charge generation layer CGL may be disposed between the plurality of stacks. The charge generation layer CGL may supply charges to each stack and control a charge balance between the stacks.

The light-emitting element layer 245 may be disposed on the entire front surface of the display area DA. Accordingly, the light-emitting element layer 245 may be disposed on a bottom surface of the trench 244 and an upper edge of the trench 244, and a gap 244G may be formed within the trench 244. At least a portion of the light-emitting element layer 245 disposed in the trench 244 may be disconnected. For example, the gap 244G may serve to disconnect the horizontal connection of the charge generation layers CGL disposed in the plurality of adjacent sub-pixels. Accordingly, leakage current can be prevented from occurring between the adjacent sub-pixels SP1, SP2, and SP3.

The second electrode 247 may be disposed on the light-emitting element layer 245. The second electrode 247 may be a common layer formed in common in the plurality of sub-pixels SP1, SP2, and SP3. The second electrode 247 may be referred to as a common electrode or a cathode electrode. The second electrode 247 may include a semi-transmissive material. For example, the second electrode 247 may include magnesium (Mg), silver (Ag), or an alloy of magnesium (Mg) and silver (Ag).

A light-emitting element may be composed of the first electrode 241, light-emitting element layer 245, and the second electrode 247.

Each of the first reflective electrode layer 220, the second reflective electrode layer 230, and the third reflective electrode layer 240 may be disposed to overlap the second electrode 247 in the vertical direction. Accordingly, the microcavity effect can be obtained between the second electrode 247 and the first reflective electrode layer 220, the second electrode 247 and the second reflective electrode layer 230, and the second electrode 247 and the third reflective electrode layer 240.

The microcavity effect is a phenomenon in which an emission spectrum varies. For example, the emission spectrum may be changed by the interference effect of light caused by the reflectance of different reflective electrode layers (e.g., 220, 230, or 240) and the transmittance of the second electrode 247 and by a varying distance between the different reflective electrode layers (e.g., 220, 230, or 240) and the second electrode 247. The microcavity effect may be used to selectively emit light of a specific wavelength.

For example, in the first sub-pixel SP1, the first reflective electrode layer 220 and the second electrode 247 are disposed to be spaced a first distance from each other. In the second sub-pixel SP2, the second reflective electrode layer 230 and the second electrode 247 are disposed to be spaced a second distance from each other. In the third sub-pixel SP3, the third reflective electrode layer 240 and the second electrode 247 are disposed to be spaced a third distance from each other. In some implementations, the first distance, the second distance, and the third distance may be formed differently. Accordingly, different colors of light may be emitted from the sub-pixels SP1, SP2, and SP3. For example, red light may be emitted from the first sub-pixel SP1, green light may be emitted from the second sub-pixel SP2, and blue light may be emitted from the third sub-pixel SP3.

An encapsulation part 300 may be disposed on the second electrode 247. The encapsulation part 300 may encapsulate the driving transistor TR and the light-emitting element thereunder. The encapsulation part 300 can prevent external moisture or foreign substances from passing therethrough. The encapsulation part 300 may include an inorganic insulation material such as silicon oxide (SiOₓ), silicon nitride (SiNₓ) or an organic insulation material such as an acrylic resin or an epoxy resin and may be formed of a single layer or multiple layers. For example, the encapsulation part 300 may include a first encapsulation layer 310, a second encapsulation layer 320, and a third encapsulation layer 330. The first encapsulation layer 310 and the third encapsulation layer 330 may include an inorganic insulation material, and the second encapsulation layer 320 may include an organic insulation material.

A pattern layer 340 may be disposed on the encapsulation part 300. For example, the pattern layer 340 may be disposed in contact with an upper surface of the encapsulation part 300. The pattern layer 340 may be disposed in each of the sub-pixels SP1, SP2, and SP3. For example, the pattern layer 340 can be disposed to cover a portion of each of the sub-pixels SP1, SP2, and SP3 and expose another portion of each of the sub-pixels SP1, SP2, and SP3. In some implementations, a plurality of pattern layers 340 may be disposed to be spaced a predetermined distance from each other in each of the sub-pixels SP1, SP2, and SP3, as shown in the example of FIG. 3. A light-transmissive portion 343 exposing the upper surface of the encapsulation part 300 may be disposed between adjacent pattern layers 340 disposed to be spaced a predetermined distance from each other.

Each pattern layer 340 may include a light-reflecting layer 341 and a light-absorbing layer 342 disposed on the light-reflecting layer 341. That is, the pattern layer 340 may include the light-reflecting layer 341 and the light-absorbing layer 342 sequentially stacked from the bottom to the top. In the present disclosure, an implementation in which the light-reflecting layer 341 and the light-absorbing layer 342 come into contact with each other will be described, but the present disclosure is not limited thereto, and in another implementation, an additional layer, such as an insulating layer, may be disposed between the light-reflecting layer 341 and the light-absorbing layer 342 so that the light-reflecting layer 341 and the light-absorbing layer 342 may not come into direct contact with each other. The light-reflecting layer 341 and the light-absorbing layer 342 may be formed to have the same pattern.

In one implementation of the present disclosure, the pattern layer 340 may form the outermost surface of the display panel 10. However, the present disclosure is not limited thereto, and a second substrate 360 may be additionally disposed on the pattern layer 340. An adhesive layer 350 may be disposed between the pattern layer 340 and the second substrate 360. The adhesive layer 350 may be disposed to cover the encapsulation part 300 and the pattern layer 340. The adhesive layer 350 may fix the second substrate 360 onto the encapsulation part 300. Accordingly, the adhesive layer 350 may be formed to come into contact with the upper surface of the encapsulation part 300, come into contact with an upper surface of the pattern layer 340, and fill the light-transmissive portion 343. For example, the adhesive layer 350 may be an optically clear resin (OCR) or an optically clear adhesive (OCA).

The second substrate 360 may be referred to as a cover window, a window cover, or cover glass. The second substrate 360 may include a glass substrate, but is not limited thereto. The second substrate 360 may include a plastic film.

As described above, the display panel and display apparatus according to one implementation of the present disclosure may emit light of different colors for each sub-pixel without using a separate color filter. The emission of different colors can be achieved by controlling light of a specific wavelength emitted by the microcavity effect caused by different positioning of the reflective electrode layer (e.g., 220, 230, or 240) in different sub-pixels. For example, the first sub-pixel SP1 may emit red light, the second sub-pixel SP2 may emit green light, and the third sub-pixel SP3 may emit blue light. Since the display apparatus according to one implementation of the present disclosure does not use a color filter, the third encapsulation layer 330 and the second substrate 360 may be disposed in contact with each other.

The reflective electrode layers 220, 230, and 240 and the pattern layer 340 will be described in detail below.

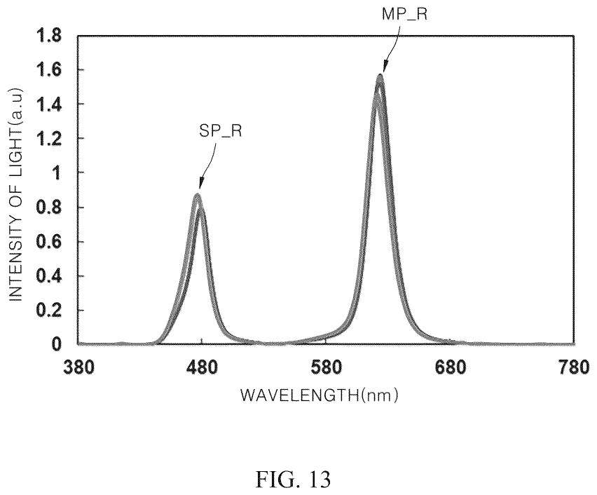

FIGS. 13 to 15 show examples of emission spectra of an element implemented using a microcavity by optimizing cavity distances between the reflective electrode layers 220, 230, and 240 and the second electrode 247 for each sub-pixel without a separate color filter. FIGS. 13, 14, and 15 show the emission spectra of the first sub-pixel, the second sub-pixel, and the third sub-pixel, respectively. The intensity of light is a value represented by a relative value based on the maximum value of the emission spectrum.

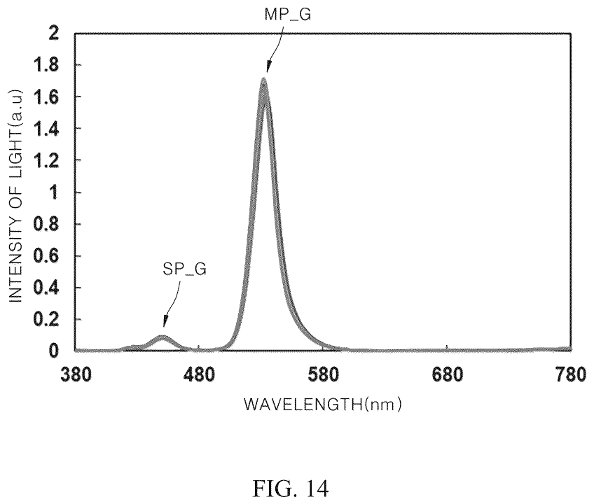

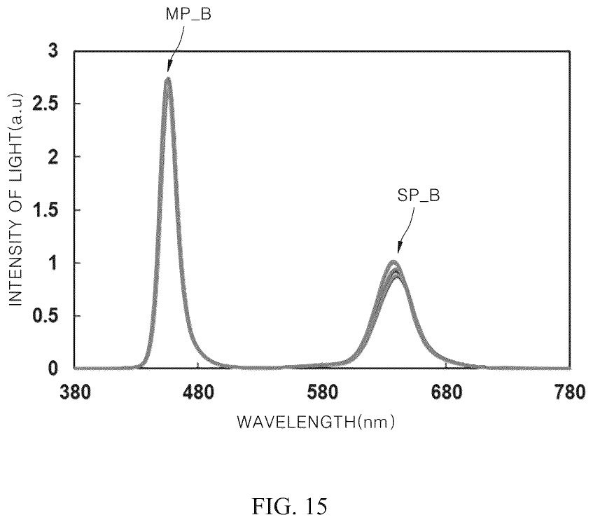

Referring to FIG. 13, it can be seen that the light emitted from the first sub-pixel has both a main emission peak MP_R at a wavelength of 600 nm to 670 nm and a sub emission peak SP_R at a wavelength of 450 nm to 500 nm. Accordingly, red light may be emitted from the first sub-pixel. Referring to FIG. 14, it can be seen that the light emitted from the second sub-pixel has both a main emission peak MP_G at a wavelength of 495 nm to 570 nm and a sub emission peak SP_G at a wavelength of 450 nm to 470 nm. Accordingly, green light may be emitted from the second sub-pixel. Referring to FIG. 15, it can be seen that the light emitted from the third sub-pixel has both a main emission peak MP_B at a wavelength of 400 nm to 495 nm and a sub emission peak SP_B at a wavelength of 590 nm to 680 nm. Accordingly, blue light may be emitted from the third sub-pixel.

Referring to FIGS. 13 to 15, the sub-emission peaks SP_R, SP_G, and SP_B that respectively appear in areas other than the main emission peaks MP_R, MP_G, and MP_B in the first to third sub-pixels may be noise peaks. The noise peaks may reduce the purity of the color emitted from the main emission peaks MP_R, MP_G, and MP_B. Accordingly, the noise peaks can be removed, thereby improving the purity of the colors emitted from the main emission peaks MP_R, MP_G, and MP_B. When the purity of the color is improved, color reproducibility can be enhanced, and colors can be represented consistently with less influence on a change in luminance.

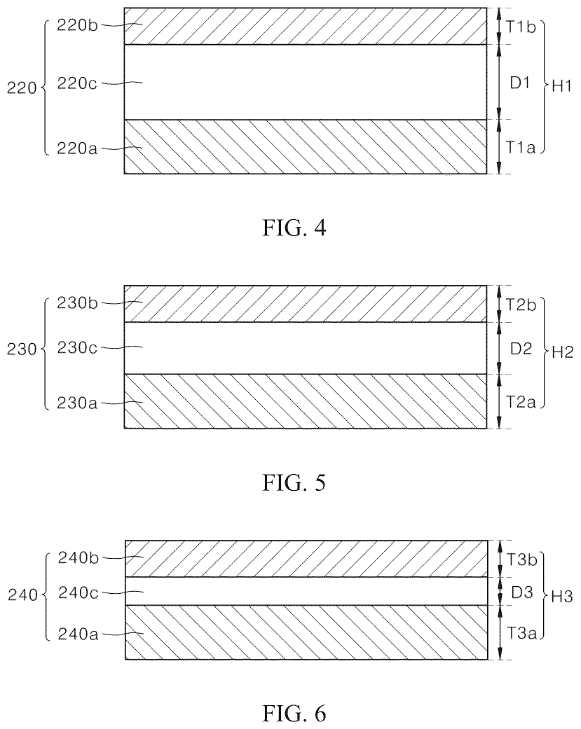

FIGS. 4 to 6 illustrates examples of an implementation of the stacked structure of the reflective electrode layers 220, 230, and 240 in each sub-pixel. Such implementations can provide a technical benefit of improving the purity of the color by significantly removing the noise peaks from each sub-pixel.

The first reflective electrode layer 220 may be formed of multiple layers. For example, the first reflective electrode layer 220 may include a first lower reflective layer 220a, a first wavelength selection layer 220c, and a first upper reflective layer 220b. The first lower reflective layer 220a and the first upper reflective layer 220b may be disposed to be spaced apart from each other. The first wavelength selection layer 220c may be disposed between the first lower reflective layer 220a and the first upper reflective layer 220b.

The first lower reflective layer 220a and the first upper reflective layer 220b may include a metal material with high reflectance, such as silver (Ag), a silver alloy, aluminum (Al), or an aluminum alloy. The first wavelength selection layer 220c may include an inorganic insulating material, an organic insulating material, a polymer, a monomer, etc. For example, the first wavelength selection layer 220c may include silicon oxide (SiOₓ), silicon nitride (SiNₓ), or polyimide. Accordingly, the first wavelength selection layer 220c may be referred to as an insulating layer.

The first lower reflective layer 220a and the first upper reflective layer 220b may be formed with different thicknesses. For example, the first lower reflective layer 220a may have a first thickness T1a, and the first upper reflective layer 220b may have a second thickness T1b. In this case, the second thickness T1b may be smaller than the first thickness T1a. Accordingly, light emitted to the first reflective electrode layer 220 (e.g., from the light-emitting element layer 245 in the first sub-pixel SP1) may pass through the first upper reflective layer 220b, reflect from the first lower reflective layer 220a, and emit upward through the first upper reflective layer 220b again. For example, the first thickness T1a of the first lower reflective layer 220a may range from 50 nm to 200 nm. The second thickness T1b of the first upper reflective layer 220b may range from 5 nm to 45 nm.

The first wavelength selection layer 220c may be formed with a thickness that allows a distance between the first lower reflective layer 220a and the first upper reflective layer 220b to be spaced a first distance D1 from each other. For example, in the first sub-pixel SP1, the first lower reflective layer 220a and the first upper reflective layer 220b may be spaced the first distance D1 of 390 nm to 410 nm from each other by the first wavelength selection layer 220c. Accordingly, the first reflective electrode layer 220 including the first lower reflective layer 220a, the first wavelength selection layer 220c, and the first upper reflective layer 220b may be formed with a first height H1.

In addition, the second reflective electrode layer 230 may be formed of multiple layers. For example, the second reflective electrode layer 230 may include a second lower reflective layer 230a, a second wavelength selection layer 230c, and a second upper reflective layer 230b. The second lower reflective layer 230a and the second upper reflective layer 230b may be disposed to be spaced apart from each other. The second wavelength selection layer 230c may be disposed between the second lower reflective layer 230a and the second upper reflective layer 230b.

The second lower reflective layer 230a and the second upper reflective layer 230b may include a metal material with high reflectance, such as silver (Ag), a silver alloy, aluminum (Al), or an aluminum alloy. The second wavelength selection layer 230c may include an inorganic insulating material, an organic insulating material, a polymer, a monomer, etc. For example, the second wavelength selection layer 230c may include silicon oxide (SiOₓ), silicon nitride (SiNₓ), or polyimide. Accordingly, the second wavelength selection layer 230c may be referred to as an insulating layer.

In some implementations, the second lower reflective layer 230a and the second upper reflective layer 230b may be formed with different thicknesses. For example, the second lower reflective layer 230a may have a first thickness T2a, and the second upper reflective layer 230b may have a second thickness T2b. In this case, the second thickness T2b may be smaller than the first thickness T2a. Accordingly, light emitted to the second reflective electrode layer 230 (e.g., from the light-emitting element layer 245 in the second sub-pixel SP2) may pass through the second upper reflective layer 230b, reflect from the second lower reflective layer 230a, and emit upward through the second upper reflective layer 230b again. For example, the first thickness T2a of the second lower reflective layer 230 a may range from 50 nm to 200 nm. The second thickness T2b of the second upper reflective layer 230b may range from 5 nm to 45 nm.

The second wavelength selection layer 230c may be formed with a thickness that allows a distance between the second lower reflective layer 230a and the second upper reflective layer 230b to be spaced a second distance D2 from each other. For example, in the second sub-pixel SP2, the second lower reflective layer 230a and the second upper reflective layer 230b may be spaced the second distance D2 of 280 nm to 300 nm from each other by the second wavelength selection layer 230c. Accordingly, the second reflective electrode layer 230 including the second lower reflective layer 230a, the second wavelength selection layer 230c, and the second upper reflective layer 230b may be formed with a second height H2.

The third reflective electrode layer 240 may be formed of multiple layers. For example, the third reflective electrode layer 240 may include a third lower reflective layer 240a, a third wavelength selection layer 240c, and a third upper reflective layer 240b. The third lower reflective layer 240a and the third upper reflective layer 240b may be disposed to be spaced apart from each other. The third wavelength selection layer 240c may be disposed between the third lower reflective layer 240a and the third upper reflective layer 240b.

The third reflective electrode layer 240 may be formed of a metal material with high reflectance, such as silver (Ag), a silver alloy, aluminum (Al), or an aluminum alloy. The third wavelength selection layer 240c may include an inorganic insulating material, an organic insulating material, a polymer, a monomer, etc. For example, the third wavelength selection layer 240c may include silicon oxide (SiOₓ), silicon nitride (SiNₓ), or polyimide. Accordingly, the third wavelength selection layer 240c may be referred to as an insulating layer.

The third lower reflective layer 240a and the third upper reflective layer 240b may be formed with different thicknesses. For example, the third lower reflective layer 240a may have a first thickness T3a, and the third upper reflective layer 240b may have a second thickness T3b. In this case, the second thickness T3b may be smaller than the first thickness T3a. Accordingly, light emitted to the third reflective electrode layer 240 (e.g., from the light-emitting element layer 245 in the third sub-pixel SP3) may pass through the third upper reflective layer 240b, reflect from the third lower reflective layer 240a, and emit upward through the third upper reflective layer 240b again. For example, the first thickness T3a of the third lower reflective layer 240a may range from 50 nm to 200 nm. The second thickness T3b of the third upper reflective layer 240b may range from 5 nm to 45 nm.

The third wavelength selection layer 240c may be formed with a thickness that allows a distance between the third lower reflective layer 240a and the third upper reflective layer 240b to be spaced a third distance D3 from each other. For example, in the third sub-pixel SP3, the third lower reflective layer 240a and the third upper reflective layer 240b may be spaced the third distance D3 of 110 nm to 130 nm from each other by the third wavelength selection layer 240c. Accordingly, the third reflective electrode layer 240 including the third lower reflective layer 240a, the third wavelength selection layer 240c, and the third upper reflective layer 240b may be formed with a third height H3.

The first reflective electrode layer 220, the second reflective electrode layer 230, and the third reflective electrode layer 240 disposed in the sub-pixels SP1, SP2, and SP3, respectively, may be disposed to have different thickness heights H1, H2, and H3. For example, the different thickness heights may be due to the different distances D1, D2, and D3 by which the upper and lower reflective layers are spaced from each other by the first wavelength selection layer 220c, the second wavelength selection layer 230c, and the third wavelength selection layer 240c, respectively, as shown in FIGS. 4-6.

In some implementations, among the first distance D1, the second distance D2, and the third distance D3, the first distance (D1) value is the largest, and the third distance D3 value is the smallest. Accordingly, the first height H1 of the first reflective electrode layer 220 disposed in the first sub-pixel SP1 is the largest, and the third height H3 of the third reflective electrode layer 240 disposed in the third sub-pixel SP3 is the smallest.

As such, the first reflective electrode layer 220, the second reflective electrode layer 230, and the third reflective electrode layer 240 disposed in the sub-pixels SP1, SP2, and SP3, respectively, can have different separation distances D1, D2, and D3 between respective upper and lower reflective layers that are separated by the first wavelength selection layer 220c, the second wavelength selection layer 230c, and the third wavelength selection layer 240c. This results in the sub-pixels SP1, SP2, and SP3 emitting light of different colors by the microcavity effect. In addition, this results in each of the first reflective electrode layer 220, the second reflective electrode layer 230, and the third reflective electrode layer 240 selectively absorbing a different specific wavelength band. Accordingly, this can provide a technical effect in that noise peaks in wavelength regions other than the main emission peak of the target wavelength region can be removed. Accordingly, this can provide a technical effect in that the purity of the color emitted from the main emission peak can be enhanced, thereby improving color reproducibility and providing a high-quality image to the user.

The above-described structure according to some implementations of the present disclosure can provide a strong microcavity structure. In particular, as a width of the emission spectrum is reduced, light in a specific wavelength region can be strongly emitted. For example, among the light generated from the light-emitting element layer 245, some light that reaches the second electrode 247 may be reflected back and travel toward the first, second, and third reflective electrode layers 220, 230, and 240. Light that has reached the first, second, and third reflective electrode layers 220, 230, and 240 may pass through the first, second, and third upper reflective layers 220b, 230b, and 240b, respectively, and be reflected from the first, second, and third lower reflective layers 220a, 230a, and 240a, respectively, and travel back toward the second electrode 247.

Thicknesses of the first, second, and third lower reflective layers 220a, 230a, and 240a and thicknesses of the first, second, and third upper reflective layers 220b, 230b, and 240b of the first, second, and third reflective electrode layers 220, 230, and 240 may be different. For example, the first, second, and third upper reflective layers 220b, 230b, and 240b disposed relatively close to the second electrode 247 may have a thickness that is smaller than a thickness of the first, second, and third lower reflective layers 220a, 230a, and 240a, so that light reflected from the second electrode 247 may be better transmitted through the upper reflective layers. In addition, the first, second, and third lower reflective layers 220a, 230a, and 240a may have a relatively large thickness to better reflect light back toward the second electrode 247.

The first, second, and third lower reflective layers 220a, 230a, and 240a and the first, second, and third upper reflective layers 220b, 230b, and 240b may be spaced apart by different distances, such as first, second, and third distances D1, D2, and D3 in the sub-pixels SP1, SP2, and SP3 by the first, second, and third wavelength selection layers 220c, 230c, and 240c, respectively. The different first, second, and third distances D1, D2, and D3 across the first, second, and third wavelength selection layers 220c, 230c, and 240c can result in absorbing and canceling out different wavelength regions in the sub-pixels SP1, SP2, and SP3. For example, in the first sub-pixel SP1 that emits red light, the first wavelength selection layer 220c may be disposed between the first lower reflective layer 220a and the first upper reflective layer 220b to absorb and cancel out a green wavelength region and a blue wavelength region. In the second sub-pixel SP2 that emits green light, the second wavelength selection layer 230c may be disposed between the second lower reflective layer 230a and the second upper reflective layer 230b to absorb and cancel out a red wavelength region and the blue wavelength region. In the third sub-pixel SP3 that emits blue light, the third wavelength selection layer 240c may be disposed between the third lower reflective layer 240a and the third upper reflective layer 240b to absorb and cancel out the red wavelength region and the green wavelength region.

As such, according to implementations described above, only the light in the specific wavelength ranges of the target colors determined by the first, second, and third wavelength selection layers 220c, 230c, and 240c are reflected and emitted from the first, second, and third reflective electrode layers 220, 230, and 240. Light in the other wavelength ranges are not emitted to the outside due to destructive interference in the first, second, and third upper reflective layers 220b, 230b, and 240b and in the first, second, and third lower reflective layers 220a, 230a, and 240a. The light in the wavelength ranges of the target colors may travel to the second electrode 247 and be emitted to the outside through constructive interference between the upper reflective layer (e.g., first, second, and third upper reflective layers 220b, 230b, and 240b) and the lower reflective layer (first, second, and third lower reflective layers 220a, 230a, and 240a).

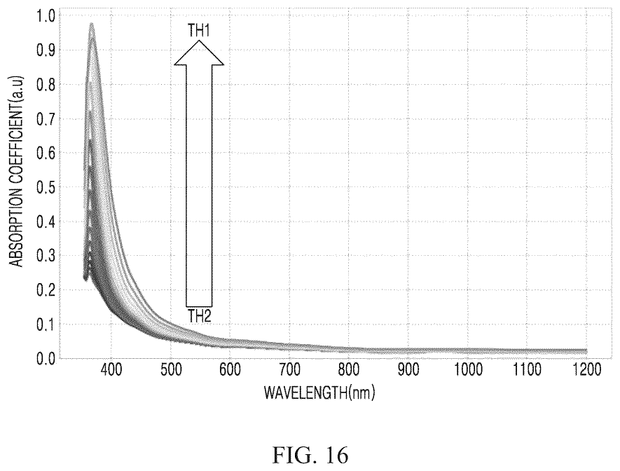

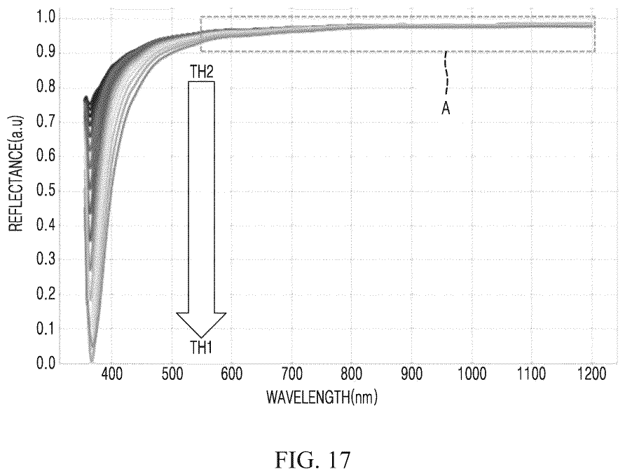

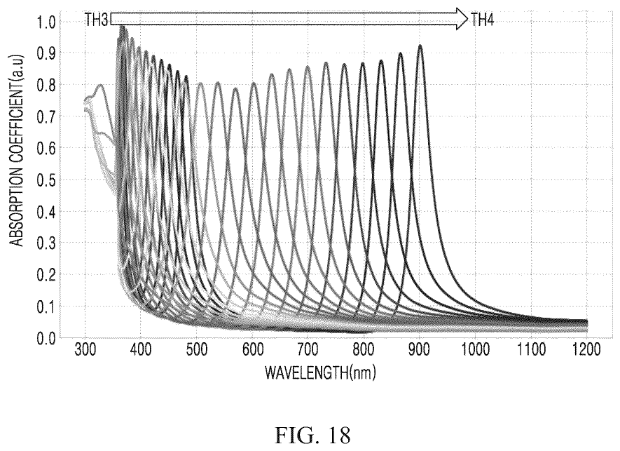

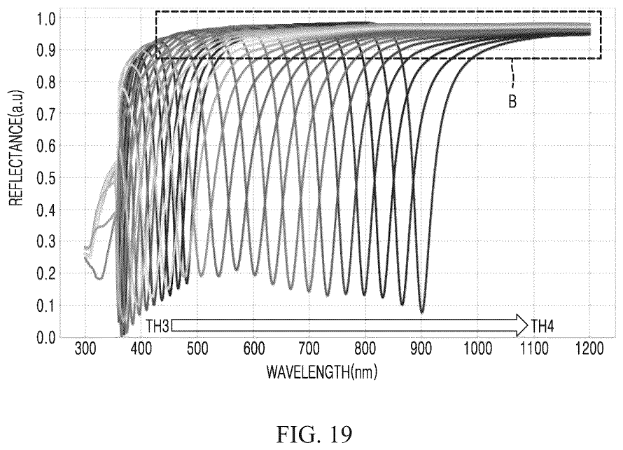

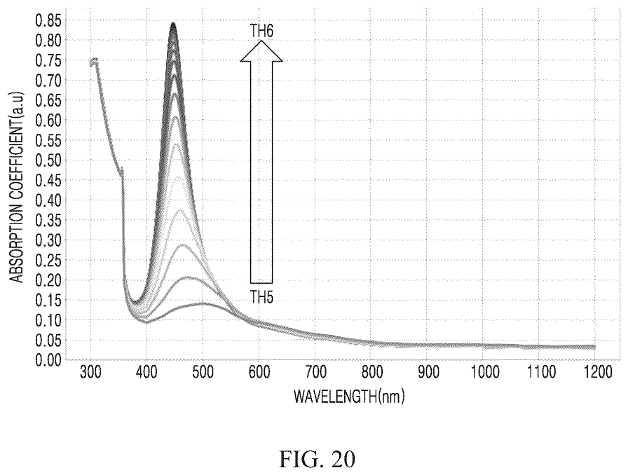

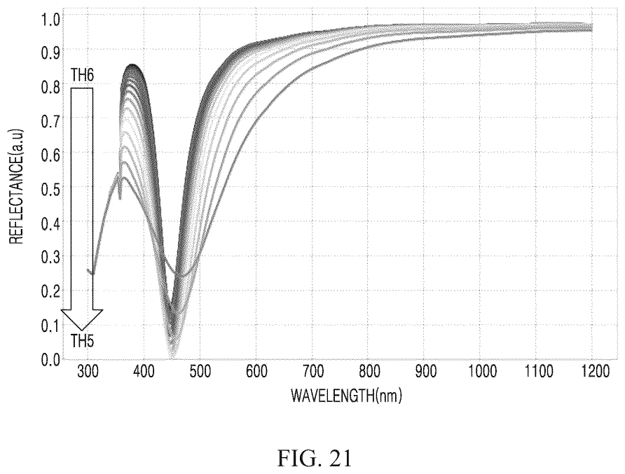

FIGS. 16 and 17 are graphs showing examples of light absorptance and reflectance according to a thickness of an upper reflective layer of a reflective electrode layer, FIGS. 18 and 19 are graphs showing examples of light absorptance and reflectance according to a thickness of a wavelength selection layer of the reflective electrode layer, and FIGS. 20 and 21 are graphs showing examples of light absorptance and reflectance according to a thickness of the lower reflective layer of the reflective electrode layer. For example, the upper reflective layer may be the first, second, and third upper reflective layers 220b, 230b, and 240b, the wavelength selection layer may be the first, second, and third wavelength selection layers 220c, 230c, and 240c, and the lower reflective layer may be the first, second, and third lower reflective layers 220a, 230a, and 240a.

Referring to FIGS. 16 and 17, it can be confirmed that absorptance increases and reflectance decreases as the thickness of the upper reflective layer (e.g., first, second, and third upper reflective layers 220b, 230b, and 240b) of the reflective electrode layer decreases from a second thickness TH2, which is relatively larger, to a first thickness TH1, which is relatively smaller. For example, the first thickness TH1 may be 20 nm and the second thickness TH2 may be 100 nm. When the thickness of the upper reflective layer is larger than 100 nm, as an absorption coefficient approaches 0, most of the light may be reflected without being absorbed. Referring to FIG. 17, it can be confirmed that reflectance does not change significantly in area “A” other than an absorption area. Accordingly, the absorptance may be selected by adjusting the thickness of the upper reflective layer.

Referring to FIGS. 18 and 19, it can be confirmed that a wavelength range with a high absorbing rate varies as the thickness of the wavelength selection layer (e.g., first, second, and third wavelength selection layers 220c, 230c, and 240c) increases from a first thickness TH3, which is relatively smaller, to a second thickness TH4, which is relatively larger. For example, the first thickness TH3 may be 10 nm and the second thickness TH4 may be 200 nm. Referring to FIG. 19, it can be confirmed that reflectance does not change significantly, as shown in area “B,” even when the thickness of the wavelength selection layer varies. Accordingly, the range of the wavelength region of light to be absorbed may be selected by adjusting the thickness of the wavelength selection layer.

Referring to FIGS. 20 and 21, it can be confirmed that the absorptance increases and reflectance decreases as the thickness of the lower reflective layer (e.g., first, second, and third lower reflective layers 220a, 230a, and 240a) of the reflective electrode layer increases from a first thickness TH5, which is relatively smaller, to a second thickness TH6, which is relatively larger. For example, the first thickness TH5 may be 10 nm and the second thickness TH6 may be 100 nm. Accordingly, by adjusting the thickness of the lower reflective layer to select a desired absorbance, the reflectance and absorptance in the lower reflective layer may be adjusted.

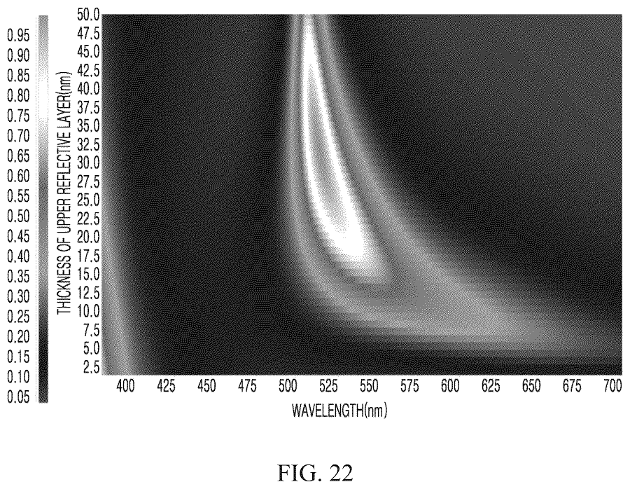

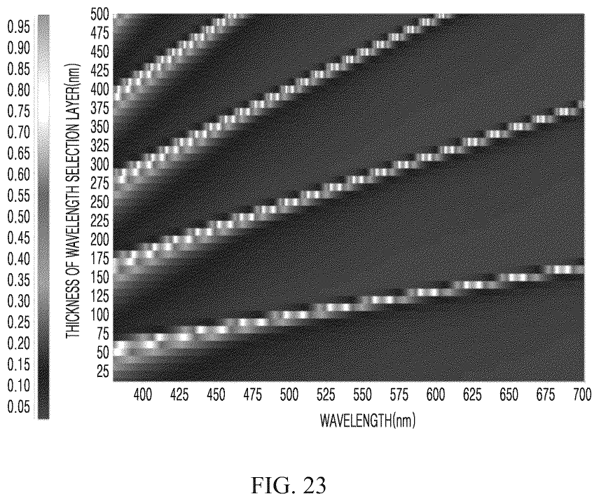

FIGS. 22 and 23 are graphs showing examples of the light absorptance according to the change in thickness of the upper electrode layer of the reflective electrode layer and the light absorptance according to the change in thickness of the insulating layer of the reflective electrode layer, respectively.

Referring to FIG. 22, in the reflective electrode layer according to one implementation, the thickness of the lower reflective layer (e.g., first, second, and third lower reflective layers 220a, 230a, and 240a) was set as 100 nm, the thickness of the wavelength selection layer (e.g., first, second, and third wavelength selection layers 220c, 230c, and 240c) was set as 100 nm, and the light absorptance was measured while changing the thickness of the upper reflective layer (e.g., first, second, and third upper reflective layers 220b, 230b, and 240b). As a result, it was confirmed that the absorptance was measured very high at about 99% when the thickness of the upper reflective layer (e.g., first, second, and third upper reflective layers 220b, 230b, and 240b) was about 38 nm.

Referring to FIG. 23, based on the above experimental results, the thickness of the upper reflective electrode layer (e.g., first, second, and third upper reflective layers 220b, 230b, and 240b) was set as 38 nm, the thickness of the lower reflective layer (e.g., first, second, and third lower reflective layers 220a, 230a, and 240a) was set as 100 nm, the light absorptance was measured while changing the thickness of the wavelength selection layer (e.g., first, second, and third wavelength selection layers 220c, 230c, and 240c). As a result, it can be confirmed that for each wavelength band, large amounts of light absorptance are present at specific discontinuous values of the thickness of the wavelength selection layer. In this way, since the thickness of the wavelength selection layer with high light absorptance for each wavelength band may be specified, the thickness of the wavelength selection layer may be set in consideration of absorptance of a desired wavelength band.

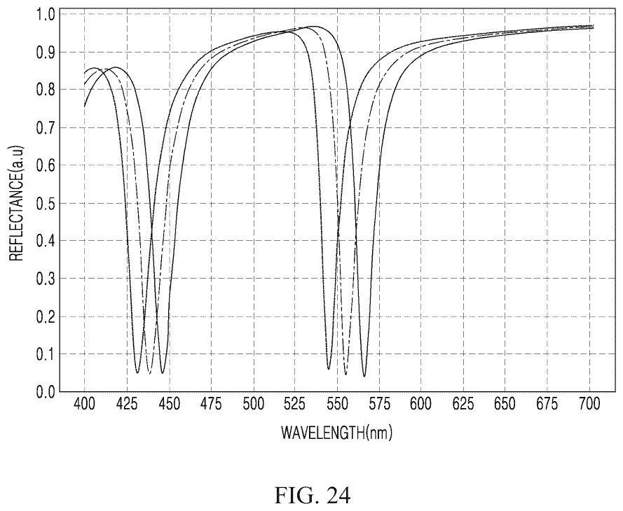

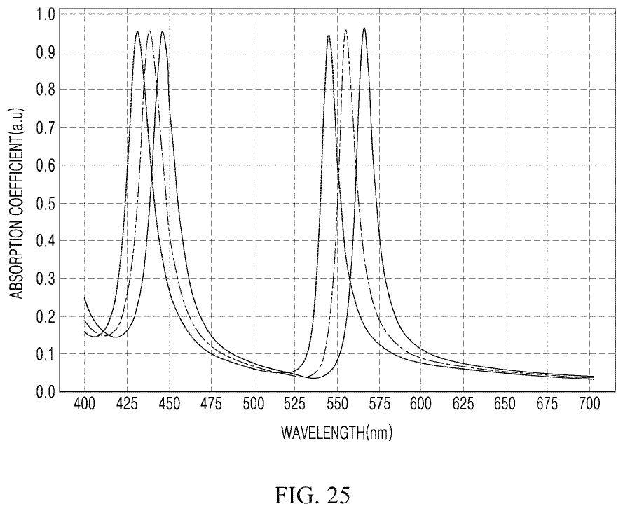

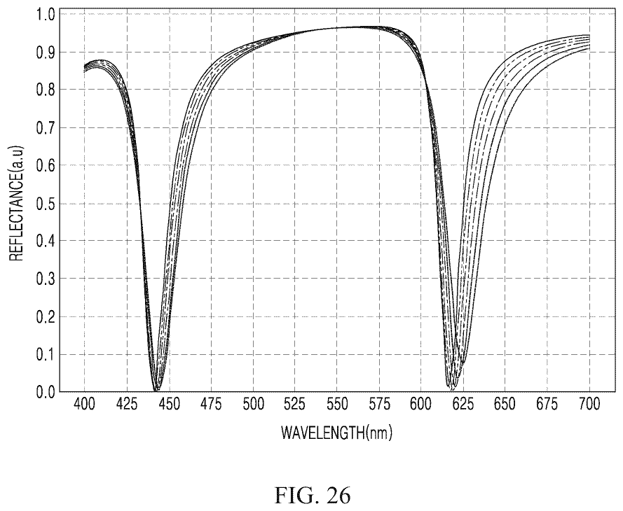

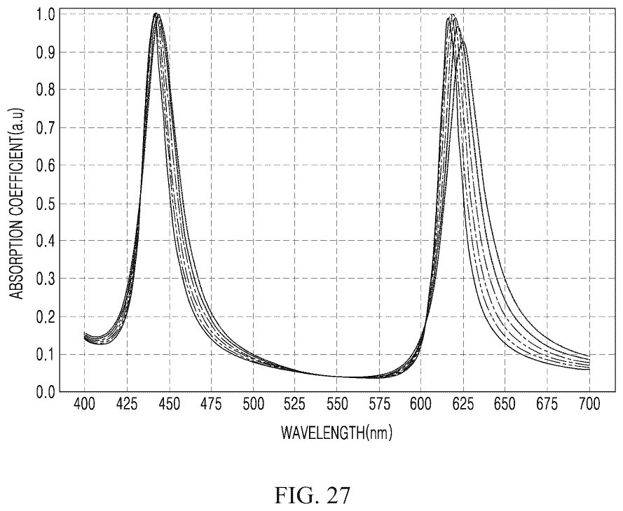

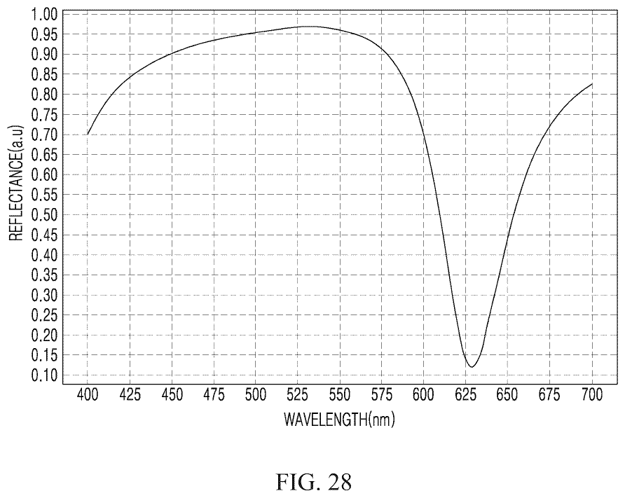

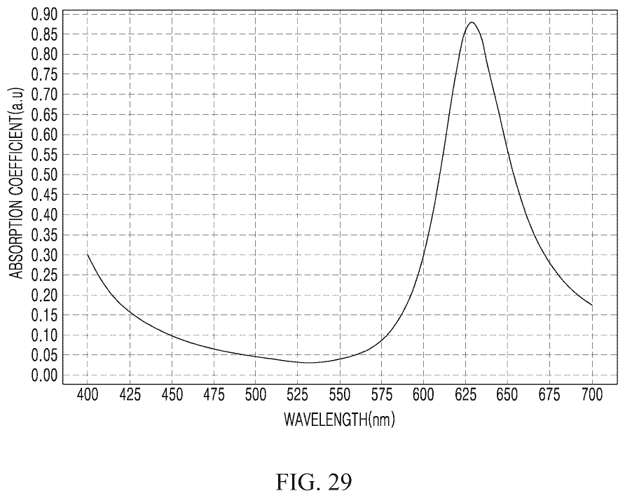

FIGS. 24-29 illustrate examples of different frequency-selective light reflectance and light absorptance in the different sub-pixels, according to different distances D1, D2, and D3 between upper and lower reflective layers. In particular, FIGS. 24 and 25 are graphs showing examples of light reflectance and light absorptance of the first sub-pixel, FIGS. 26 and 27 are graphs showing examples of light reflectance and light absorptance of the second sub-pixel, and FIGS. 28 and 29 are graphs showing examples of light reflectance and light absorptance of the third sub-pixel.

Referring to FIGS. 24 and 25, in the first sub-pixel, the first wavelength selection layer 220c was disposed so that the first distance D1 between the first lower reflective layer 220a and the first upper reflective layer 220 b was maintained in a range from 390 nm to 410 nm. It can be seen that red light is reflected and emitted from the first sub-pixel as reflectance approaches 1 in the wavelength range of 600 nm to 670 nm, which corresponds to red light. In addition, it can be seen that wavelength ranges other than the wavelength range of red light are absorbed in the first upper reflective layer 220b and not emitted to the outside as the absorptance approaches 0. In addition, in an area in which reflectivity ranges from 450 nm to 550 nm, light emission is significantly suppressed due to destructive interference.

Referring to FIGS. 26 and 27, in the second sub-pixel, the second wavelength selection layer 230c was disposed so that the second distance D2 between the second lower reflective layer 230a and the second upper reflective layer 230b was maintained in a range from 280 nm to 300 nm. It can be seen that green light is reflected and emitted from the second sub-pixel as reflectance approaches 1 in the wavelength range of 495 nm to 570 nm, which corresponds to green light. In addition, it can be seen that wavelength ranges other than the wavelength range of green light are absorbed in the second upper reflective layer 230b and not emitted to the outside as the absorptance approaches 0. In addition, in an area with reflectivity in the remaining region other than the wavelength region of green light, light emission is significantly suppressed due to destructive interference.

Referring to FIGS. 28 and 29, in the third sub-pixel, the third wavelength selection layer 240c was disposed so that the third distance D3 between the third lower reflective layer 240a and the third upper reflective layer 240b was maintained in a range from 110 nm to 130 nm. As reflectance increases in the wavelength range of 450 nm to 495 nm, which corresponds to a long wavelength part of the wavelength range of blue light, it can be seen that blue light is reflected and emitted from the third sub-pixel. In addition, it can be seen that wavelength ranges other than the wavelength range of blue light are absorbed in the third upper reflective layer 240b and not emitted to the outside as the absorptance approaches 0. In addition, in an area with reflectivity in the remaining region other than the wavelength region of blue light, light emission is significantly suppressed due to destructive interference. In addition, blue light in a short wavelength range of 300 nm to 400 nm may be selectively removed. In a head-mounted display product where all of the emitted light enters the user's eyes and affects the retina, blue light in a short wavelength range of 300 nm to 400 nm, which can reduce the function of the retina, can be blocked by adjusting the third wavelength selection layer 240c.

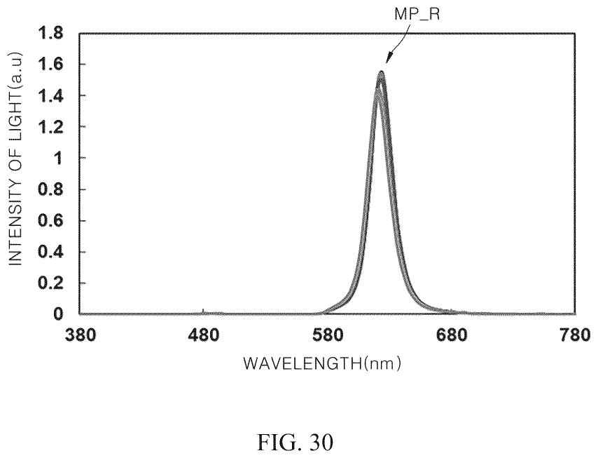

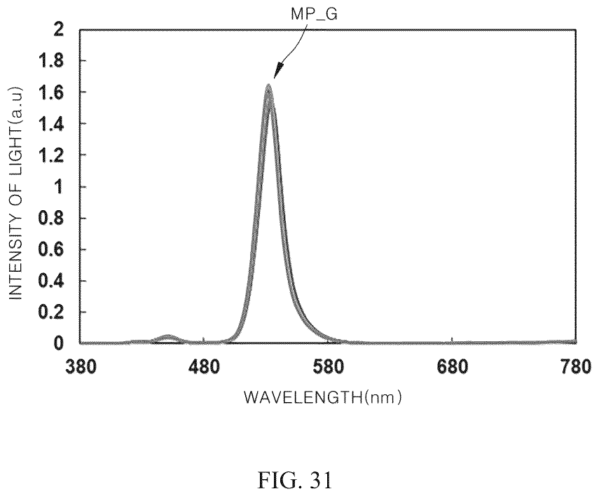

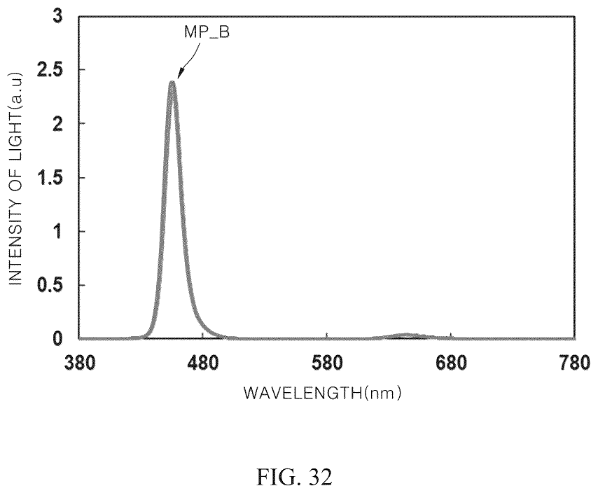

FIGS. 30-32 illustrate examples of different frequency-selective emission spectra for the different sub-pixels. In particular, FIG. 30 shows an example emission spectrum of a first sub-pixel on which a first reflective electrode layer is disposed according to an implementation of the present disclosure, FIG. 31 shows an example emission spectrum of a second sub-pixel on which a second reflective electrode layer is disposed according to an implementation of the present disclosure, and FIG. 32 shows an example emission spectrum of a third sub-pixel on which a third reflective electrode layer is disposed according to an implementation of the present disclosure.

Referring to FIG. 30, it can be seen that the light emitted from the first sub-pixel SP1 exhibits only the main emission peak MP_R within a wavelength range from 600 nm to 670 nm. Accordingly, red light may be emitted from the first sub-pixel SP1. Referring to FIG. 31, it can be seen that the light emitted from the second sub-pixel SP2 exhibits only the main emission peak MP_G within a wavelength range from 495 nm to 570 nm. Accordingly, green light may be emitted from the second sub-pixel SP2. In addition, referring to FIG. 32, it can be seen that the light emitted from the third sub-pixel SP3 exhibits only the main emission peak MP_B within a wavelength range from 450 nm to 495 nm. Accordingly, blue light may be emitted from the third sub-pixel SP3.

Referring to FIGS. 30 to 32, it can be seen that the display panel and display apparatus according to one implementation of the present disclosure generate very minimal noise peaks in areas other than the main emission peaks MP_R, MP_G, and MP_B in the first to third sub-pixels.

Accordingly, the purity of the colors emitted from the first sub-pixel, the second sub-pixel, and the third sub-pixel can be enhanced. For example, since the main emission peaks MP_R, MP_G, and MP_B of the first to third sub-pixels have narrow widths and are sharply shaped, light of high color purity may be emitted without contamination from adjacent colors. Accordingly, since the image may be represented with a color closer to nature, user immersion can be further enhanced.

According to one implementation of the present disclosure, the reflective electrode layer disposed in each sub-pixel may be formed in a multi-layer structure including the lower reflective layer, the wavelength selection layer, and the upper reflective layer, and the separation distance between the lower reflective layer and the upper reflective layer may be adjusted by the thickness of the wavelength selection layer. In addition, the lower reflective layer and the upper reflective layer may be disposed with different thicknesses.

Accordingly, the light in the remaining wavelength range other than the light in the wavelength range of the target color to be emitted from each sub-pixel may be absorbed by adjusting the thickness of the upper reflective layer, and thus can be prevented from being emitted to the outside. In addition, the light in the remaining wavelength range other than the light in the wavelength range of the target color can be prevented from being emitted to the outside by destructive interference. Accordingly, the color purity of the display panel and the display apparatus can be enhanced.

In addition, since the separation distance between the lower reflective layer and the upper reflective layer may be adjusted to selectively emit light of a specific wavelength by the distance between the reflective electrode and the second electrode, there is a reduced need for a separate color filter. Accordingly, there is less need to apply an expensive semiconductor exposure device, which can help reduce the price of the finished product. In scenarios where the color filter can be omitted, this can help simplify the process method and implementing process optimization. In addition, since the color filter can be omitted, the amount of light lost while passing through the color filter can be prevented, thereby increasing optical efficiency.

Hereinafter, the pattern layer 340 will be described in more detail with further reference to FIGS. 3 and 7 to 12.

As described above, the pattern layer 340 may be disposed on the encapsulation part 300. The pattern layer 340 disposed in each sub-pixel may be provided as a plurality of pattern layers. The plurality of pattern layers 340 disposed in the first sub-pixel SP1 may be disposed to overlap the first reflective electrode layer 220 in the vertical direction. The plurality of pattern layers 340 disposed in the second sub-pixel SP2 may be disposed to overlap the second reflective electrode layer 230 in the vertical direction. The plurality of pattern layers 340 disposed in the third sub-pixel SP3 may be disposed to overlap the third reflective electrode layer 240 in the vertical direction. In this case, the plurality of pattern layers 340 may be disposed to be spaced apart from each other.

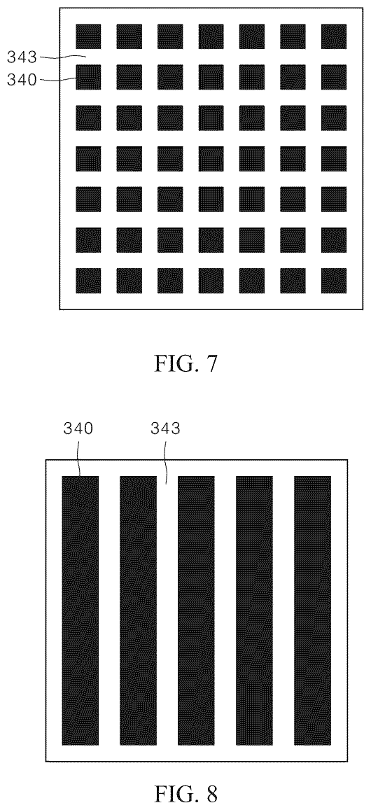

Referring to FIG. 7, the plurality of pattern layers 340 disposed to correspond to one sub-pixel based on the plan view may be disposed in the form of a matrix. For example, the plurality of pattern layers 340 may be arranged to be spaced a predetermined distance from each other in the first direction and the second direction. FIG. 7 shows an example in which the plurality of pattern layers 340 are disposed to have a regular pattern, but the present disclosure is not limited thereto, and the plurality of pattern layers 340 may be disposed in an irregular pattern. Areas not covered by the pattern layers 340 based on one sub-pixel may become the light-transmissive portion 343 in which light is not reflected or absorbed by the pattern layer 340.

Referring to FIG. 8, the plurality of pattern layers 340 disposed to correspond to one sub-pixel based on the plan view may be disposed in the form of a slit extending in one direction. For example, in one implementation, the plurality of pattern layers 340 extending in the first direction may be arranged to be spaced a predetermined distance from each other. For example, in another implementation, the plurality of pattern layers 340 extending in the second direction may be arranged to be spaced a predetermined distance from each other. The areas not covered by the pattern layers 340 based on one sub-pixel may become the light-transmissive portion 343 in which light is not reflected or absorbed by the pattern layer 340.

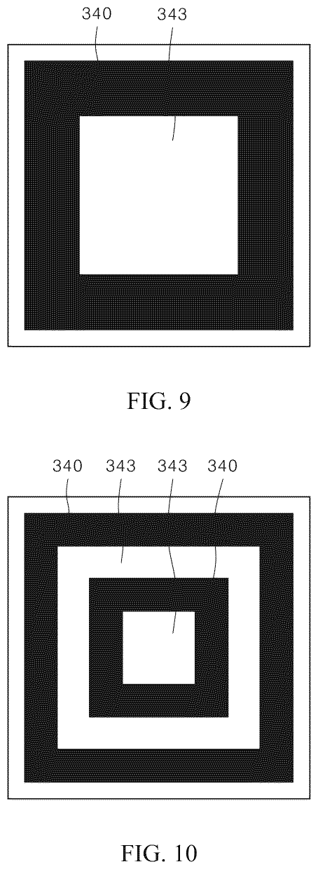

Referring to FIG. 9, the pattern layer 340 may be formed along an edge of one sub-pixel based on the plan view. That is, the pattern layer 340 may be formed along an edge of the reflective electrode layer disposed thereunder based on the plan view. For example, the pattern layer 340 may be formed in a closed loop shape. Accordingly, the light-transmissive portion 343 may be formed on a central portion of the pattern layer 340. In one implementation, the pattern layer 340 may be disposed to be spaced a predetermined distance inward from the edge of the reflective electrode layer. In another implementation, the pattern layer 340 may be disposed to overlap the edge of the reflective electrode layer in the vertical direction.

Referring to FIG. 10, based on the plan view, the plurality of pattern layers 340 formed in a closed loop shape may be disposed. For example, based on the plan view, one pattern layer 340 may be formed in a closed loop shape along the edge of the reflective electrode layer disposed thereunder. In addition, another pattern layer 340 may be formed in a smaller closed loop shape on the central portion of one pattern layer 340 formed in a closed loop shape along the edge of the reflective electrode layer. The plurality of pattern layers 340 may be disposed to be spaced a predetermined distance from each other. Accordingly, the light-transmissive portion 343 may be formed between the central portion of the pattern layer 340 and the plurality of pattern layers 340.

The pattern layer 340 may include the light-reflecting layer 341 and the light-absorbing layer 342 disposed on the light-reflecting layer 341. Accordingly, the light-reflecting layer 341 may be disposed to face the light-emitting element layer 245 that is disposed thereunder and emits light. The light-reflecting layer 341 may include a metal material having high reflectivity, such as silver (Ag), a silver alloy, aluminum (Al), or an aluminum alloy.

Referring to FIG. 3, the light emitted from the light-emitting element layer 245 may include first light EL1 emitted upward or second light EL2 emitted downward. As described above, the display panel 10 and the display apparatus 1 according to the implementation of the present disclosure may emit different colors from different sub-pixels due to the microcavity effect resulting from the different cavity distances between the second electrode 247 and the reflective electrode layers 220, 230, and 240 for each sub-pixel. Accordingly, to achieve the microcavity effect, the light emitted from the light-emitting element layer 245 is emitted to the reflective electrode layers 220, 230, and 240 disposed thereunder, such as the second light EL2 shown in FIG. 3.

In this case, the first light EL1, which is a portion of the light emitted from the light-emitting element layer 245, may be emitted upward in a direction opposite to a direction in which the reflective electrode layers 220, 230, and 240 are disposed. In this case, when there is no pattern layer 340, the first light EL1 may pass through the encapsulation part 300 and be emitted to the outside. In such scenarios, a problem can arise since the first light EL1 emitted directly to the outside without passing through the reflective electrode layers 220, 230, and 240 is light for which the microcavity effect is not actually achieved, and the colors required for each sub-pixel cannot be properly implemented. For example, the first light EL1 emitted directly to the outside without passing through the reflective electrode layers 220, 230, and 240 may be white light.

Accordingly, according to the implementation of the present disclosure, by arranging the pattern layer 340 including the light-reflecting layer 341 on the encapsulation part 300, the light emitted from the light-emitting element layer 245, such as the first light EL1, which is emitted upward without passing through the lower reflective electrode layers 220, 230, and 240, may be reflected downward so that the light may be emitted to the outside after passing through the lower reflective electrode layers 220, 230, and 240 as much as possible without being directly emitted to the outside of the display panel 10. That is, some of the light emitted from the light-emitting element layer 245 may be reflected from the light-reflecting layer 341 to the reflective electrode layers 220, 230, and 240. Some of the light emitted from the light-emitting element layer 245 may be emitted directly to the outside of the display panel 10 without reflected by the light-reflecting layer 341, but due to the dense arrangement of the pattern layer 340 according to various implementations, the light not reflected by the pattern layer 340 can be reduced as much as possible.

In this way, third light EL3, which is the reflected light reflected from the light-reflecting layer 341 to the reflective electrode layers 220, 230, and 240, may be re-reflected by the reflective electrode layers 220, 230, and 240. The light re-reflected by the reflective electrode layers 220, 230, and 240 can properly implement the colors required for each sub-pixel by achieving the microcavity effect. Some of the re-reflected light re-reflected from the reflective electrode layers 220, 230, and 240 may be emitted to the outside of the display panel 10 through the light-transmissive portion 343 between the plurality of pattern layers 340, but fourth light EL4, which is some of the re-reflected light, may be reflected back to the reflective electrode layers 220, 230, and 240 from the light-reflecting layer 341 of the pattern layer 340. In this way, fifth light EL5, which is the light reflected back from the light-reflecting layer 341, may become sixth light EL6 that is re-reflected from the reflective electrode layers 220, 230, and 240 disposed below the light-reflecting layer 341 and emitted to the outside of the display panel 10. In this case, some light that is re-reflected from the reflective electrode layers 220, 230, and 240 may be subjected to a process of being reflected from the light-reflecting layer 341 back to the reflective electrode layers 220, 230, and 240 several times repeatedly.

According to the above implementation of the present disclosure, by arranging the light-reflecting layer 341 on the light-emitting element layer 245, at least some of the light emitted upward from the light-emitting element layer 245 may be reflected to the reflective electrode layers 220, 230, and 240 positioned under the light-reflecting layer 341. Accordingly, among the light emitted from the light-emitting element layer 245, the light that is emitted directly to the outside of the display panel 10 without achieving the microcavity effect by not passing through the reflective electrode layers 220, 230, and 240 can be reduced, thereby improving the color sensation of the display panel 10.

In addition, according to the implementation of the present disclosure, by repeating the process in which at least some of the light reflected from the reflective electrode layers 220, 230, and 240 is re-reflected from the light-reflective layer 341 of the pattern layer 340 to the reflective electrode layers 220, 230, and 240 at least several times, the noise peaks included in the light can be removed more effectively. Accordingly, color purity and color reproducibility can be enhanced, and colors can be represented consistently with less influence on the change in brightness.

In some implementations, the light-absorbing layer 342 may be disposed to face an upper outer surface of the display panel 10 so that external light incident from the outside may be incident on the light-absorbing layer 342. For example, the light-absorbing layer 342 may include a material with high light absorptance. For example, the light-absorbing layer 342 may include a black matrix. The light-absorbing layer 342 may serve to absorb external light incident from the outside.

Accordingly, according to implementations of the present disclosure, the light-absorbing layer 342 having a predetermined pattern may be disposed on the light-emitting element layer 245 in each sub-pixel and thus may replace the role of a polarizing plate. Accordingly, the light-absorbing layer 342 can effectively absorb external light, thereby reducing the reflectivity of the display panel and preventing a reduction in brightness that can occur due to the arrangement of a polarizing plate.

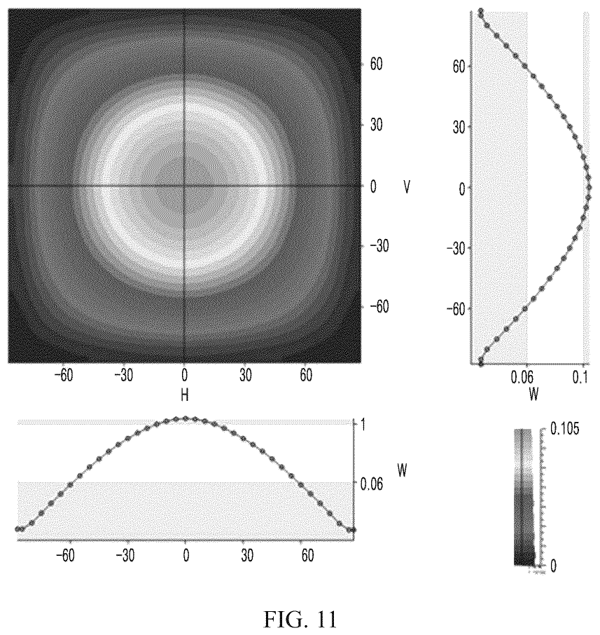

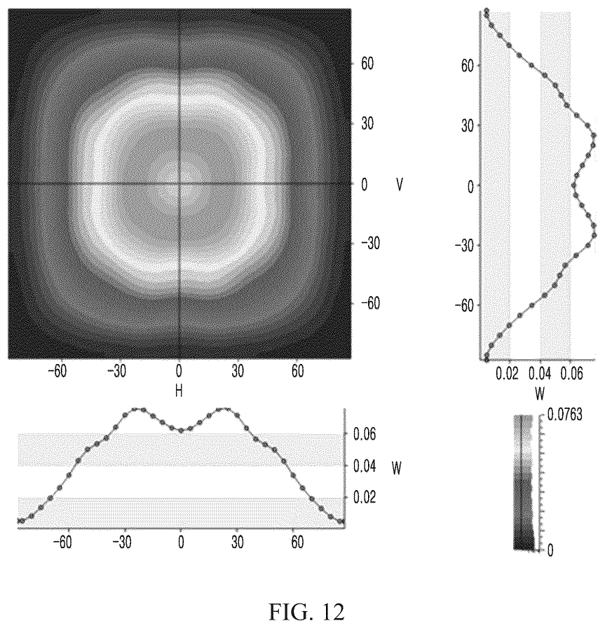

FIG. 11 is a view showing an example of a light distribution of a display panel without a pattern layer (e.g., without a pattern layer 340) disposed, and FIG. 12 is a view showing an example of light distribution of a display panel with the pattern layer (e.g., with pattern layer 340) disposed. FIGS. 11 and 12 show examples of a light distribution in a horizontal H direction and a light distribution in a vertical V direction, respectively, together with a two-dimensional heat map for each structure. Hereinafter, the implementation according to FIG. 11 is referred to as a first implementation, and the implementation according to FIG. 12 is referred to as a second implementation, and a comparison between the two are described.

As a result of measuring the light distribution of the display panel according to the first implementation, it can be confirmed that the light distribution has a Gaussian shape in which a central portion is the brightest and the brightness decreases toward edges. In addition, as a result of measuring the light distribution of the display panel according to the second implementation, there is a relatively dark area in a central portion, but a bright area appears around the dark area, and thus it can be confirmed that the light intensity at the center is somewhat low, but the light is concentrated on the center.

In the case of the pattern layer 340 according to the second implementation, in one example, based on a unit area with a width and height of 100 μm each, the total area of the pattern layers 340 was measured to be 70 μm in both width and height. That is, the total area of the pattern layers 340 per unit area was measured based on an example corresponding to 49%.

In this case, a measured internal luminance value emitted from the display panel in the first implementation was measured to be 0.304 W, and a measured internal luminance value emitted from the display panel in the second implementation was measured to be 0.237 W. That is, it can be confirmed that the internal luminance value of the second implementation (with a pattern layer 340) is about 77.9% of the internal luminance value of the first implementation.

In addition, the reflectivity of the display panel according to the first implementation was measured to be 0.956 W, and the reflectivity of the display panel according to the second implementation was measured to be 0.501 W. That is, it can be confirmed that the reflectivity of the second implementation (with a pattern layer 340) is about 52.3% of the reflectivity of the first implementation.

That is, in the case of the second implementation with a pattern layer 340 according to implementations of the present disclosure, reflectivity decreases similarly to the area ratio of the light-absorbing layer of the pattern layer compared to the first implementation, but it can be confirmed that the internal luminance value increases by about 40% or more compared to the reduction in the area due to the pattern layer 340.

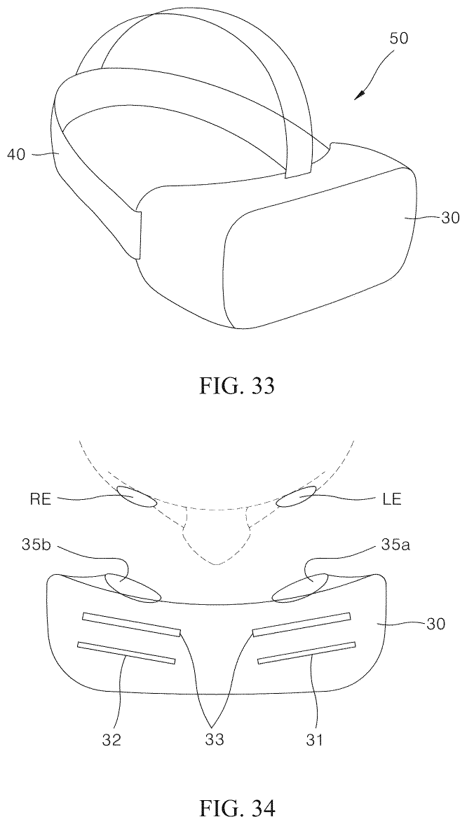

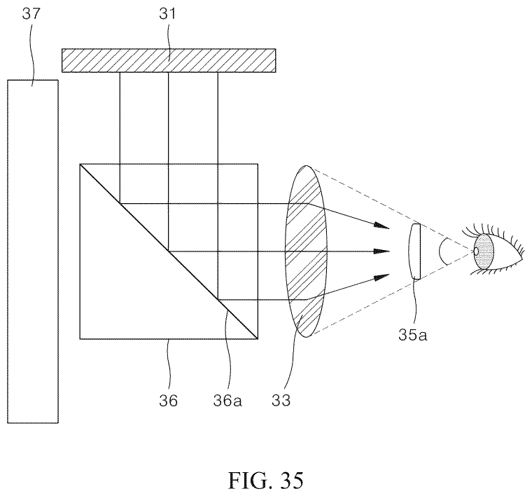

FIGS. 33 to 35 show examples of a head-mounted display apparatus including the display apparatus according to one implementation of the present disclosure. Specifically, FIG. 33 is a schematic perspective view of an example of a head-mounted display apparatus including the display apparatus according to the implementation of the present disclosure, and FIG. 34 is a top view and side view of an example of the head-mounted display apparatus implementing virtual reality (VR). In addition, FIG. 35 is a side view showing an example of a head-mounted display apparatus implementing augmented reality (AR).

Referring to FIG. 33, a head-mounted display (HMD) apparatus including the display apparatus according to the implementation of the present disclosure may include a case part 30 and a head-mounting band 40. The case part 30 includes components, such as a display device, a lens array, an eyepiece, a sound device, an accelerometer, and a position sensor, therein. The head-mounting band 40 is fixed to the case part 30. An example in which the head-mounting band 40 is formed to surround an upper surface and both side surfaces of a user's head, but the implementations of the present disclosure are not limited thereto. The head-mounting band 40 is used to fix the HMD apparatus to a user's head. In another example, the head-mounting band 40 may be an eyeglass frame or a helmet-shaped structure that fully surrounds the user's head. The HMD apparatus may include the above display panel and display apparatus according to the implementation of the present disclosure and provide an image implementing VR or an image implementing AR to the user.

Referring to FIG. 34, the HMD apparatus implementing VR may include a first display panel 31, a second display panel 32, a first lens 33, a left-eye lens 35a, and a right-eye lens 35b. The first display panel 31 may be referred to as a left-eye display panel, the second display panel 32 may be referred to as a right-eye display panel, the first lens 33 may be referred to as a lens array, and the left-eye lens 35a and the right-eye lens 35b may be referred to as a pair of second lenses. The first display panel 31, the second display panel 32, the first lens 33, the left-eye lens 35a, and the right-eye lens 35b may be stored in the case part 30.

The first display panel 31 and the second display panel 32 may display the same image. When the same image is implemented on each of the first display panel 31 and the second display panel 32, the user may view a 2D image through the HMD apparatus. Alternatively, the first display panel 31 may display a left-eye image, and the second display panel 32 may display a right-eye image different from the left-eye image. In this case, the user may view a three-dimensional image through the HMD apparatus. Each of the first display panel 31 and the second display panel 32 may include one of the display panel according to the implementation of the present disclosure and a modified example thereof.

The first lens 33 may be positioned to be spaced apart from each of a left-eye lens 35a and the first display panel 31 and disposed between the left-eye lens 35a and the first display panel 31. That is, the first lens 33 may be positioned in front of the left-eye lens 35a and behind the first display panel 31. In addition, the first lens 33 may be positioned to be spaced apart from each of a right-eye lens 35b and the second display panel 32 and disposed between the right-eye lens 35b and the second display panel 32. That is, the first lens 33 may be positioned in front of the right-eye lens 35b and behind the second display panel 32. The first lens 33 may include a micro lens array, but is not limited thereto. In one example, the first lens 33 may include a pin hole array. The image displayed on the first display panel 31 or the second display panel 32 may appear magnified to the user through the first lens 33. A left eye LE of the user may be positioned behind the left-eye lens 35a, and a right eye RE of the user may be positioned behind the right-eye lens 35b.

Referring to FIG. 35, the HMD apparatus implementing AR may include the first display panel 31, the first lens 33, the second lens 35a, a transmissive reflector 36, and a transmissive window 37. For convenience of description, only the configuration of the left eye is shown in FIG. 35, and the configuration of the right eye is also the same as or similar to that of the left eye.

The first display panel 31, the first lens 33, the second lens 35a, the transmissive reflector 36, and the transmissive window 37 may be stored in the case part 30. The first display panel 31 may be disposed on one side, for example, an upper side, of the transmissive reflector 36 without covering the transmissive window 37. Accordingly, the first display panel 31 may provide an image to the transmissive reflector 36 without covering an external background seen through the transmissive window 37. The first display panel 31 may include one of the display panels according to the implementation of the present disclosure and modified examples thereof. The first lens 33 may be provided between the second lens 35a and the transmissive reflector 36. The left eye of the user is positioned behind the second lens 35a.

The transmissive reflector 36 is disposed between the first lens 33 and the transmissive window 37. The transmissive reflector 36 may include a reflective surface 36a that transmits some light and reflects the others. The reflective surface 36a includes a semi-transmissive metal film. For example, the semi-transmissive metal film may be made of a semi-transmissive metal material such as magnesium (Mg), silver (Ag), or an alloy of magnesium (Mg) and silver (Ag). The reflective surface 36a is formed so that the image displayed on the first display panel 31 proceeds to the first lens 33. Accordingly, the user may view both the external background visible through the transmissive window 37 and the image displayed on the first display device 31. That is, since the user may view the real background and the virtual image as one image by allowing the real background and the virtual image to overlap each other, the AR can be implemented.

According to the implementations of the present disclosure, the HMD apparatus can be implemented using the display panel with improved viewing angle characteristics, thereby providing a consistent visual experience to the user and maximizing user immersion.

Although the implementations of the present disclosure have been described in more detail with reference to the accompanying drawings, the present disclosure is not necessarily limited to these implementations, and various modifications may be carried out without departing from the technical idea of the present disclosure. Accordingly, the implementations disclosed in the present disclosure are not intended to limit the technical idea of the present disclosure, but is intended to describe the same, and the scope of the technical idea of the present disclosure is not limited by these implementations. Accordingly, it should be understood that the above-described implementations are illustrative and not restrictive in all aspects.

What is claimed is:

1. A display panel comprising:
a substrate including sub-pixels;
a reflective electrode layer disposed on the substrate in each of the sub-pixels;
a first electrode disposed on the reflective electrode layer;
a light-emitting element layer disposed on the first electrode;
a second electrode disposed on the light-emitting element layer; and
one or more pattern layers disposed on the second electrode to overlap each of the sub-pixels,
wherein each of the one or more pattern layers includes a light-reflecting layer and a light-absorbing layer sequentially stacked.

2. The display panel of claim 1, wherein the one or more pattern layers includes a plurality of pattern layers that are disposed on each of the sub-pixels, and
the plurality of pattern layers are disposed to be spaced apart from each other.

3. The display panel of claim 2, wherein the plurality of pattern layers are disposed in a form of a matrix in a plan view.

4. The display panel of claim 2, wherein the plurality of pattern layers are arranged in a plan view as a plurality of slits each extending along a first direction and spaced apart from each other in a second direction.

5. The display panel of claim 1, wherein the one or more pattern layers include a pattern layer that extends along edges of the reflective electrode layer in a plan view.

6. The display panel of claim 1, wherein the light-reflecting layer of the pattern layer includes silver (Ag) or aluminum (Al).

7. The display panel of claim 1, wherein the light-absorbing layer of the pattern layer includes a black matrix.

8. The display panel of claim 1, wherein the reflective electrode layer has different thicknesses in each of the sub-pixels.

9. The display panel of claim 1, wherein the reflective electrode layer includes:
a lower reflective layer;
an insulating layer disposed on the lower reflective layer; and
an upper reflective layer disposed on the insulating layer, and
the lower reflective layer is thicker than the upper reflective layer.

10. The display panel of claim 9, wherein the insulating layer of the reflective electrode layer has different thicknesses in each of the sub-pixels.

11. A display panel comprising:
a substrate including sub-pixels;
a reflective electrode layer disposed on the substrate in each of the sub-pixels;
a light-emitting element layer disposed on the reflective electrode layer to correspond to the sub-pixels; and
one or more light-reflecting layers disposed on the light-emitting element layer of each of the sub-pixels to cover a portion of the reflective electrode layer,
wherein a part of light emitted from the light-emitting element layer is reflected from the one or more light-reflecting layers to the reflective electrode layer, then re-reflected from the reflective electrode layer, and emitted to the outside.

12. The display panel of claim 11, wherein a part of the re-reflected light that is re-reflected from the reflective electrode layer is reflected from the one or more light-reflecting layers back to the reflective electrode layer, then re-reflected from the reflective electrode layer, and emitted to the outside.

13. The display panel of claim 11, further comprising a light-absorbing layer that is disposed on the one of more light-reflecting layer and that is configured to absorb externally incident light.

14. The display panel of claim 13, wherein the light-absorbing layer is disposed in contact with the one or more light-reflecting layers and has a same pattern as the one or more light-reflecting layers so that the light-absorbing layer and the one or more light-reflecting layers form a pattern layer.

15. The display panel of claim 14, wherein the pattern layer includes a plurality of pattern layers, and
the plurality of pattern layers are disposed to be spaced apart from each other with a light-transmissive portion formed between adjacent pattern layers.

16. The display panel of claim 11, wherein the reflective electrode layer has different thicknesses in each of the sub-pixels.

17. The display panel of claim 11, wherein the reflective electrode layer includes:
a lower reflective layer;
an insulating layer disposed on the lower reflective layer; and
an upper reflective layer disposed on the insulating layer, and
the insulating layer has a different thickness in each of the sub-pixels.

18. The display panel of claim 17, wherein a thickness of the lower reflective layer of the reflective electrode layer is greater than a thickness of the upper reflective layer of the reflective electrode layer.

19. A display apparatus comprising:
a case part that is configured to house one or more display panels including the display panel of claim 1.

20. The display apparatus of claim 19, wherein the one or more display panels includes a first display panel and a second display panel that are disposed to be spaced apart from each other, and
the case part further houses a left-eye lens disposed between the first display panel and a left eye of a user, and a right-eye lens disposed between the second display panel and a right eye of the user.

21. A display panel comprising:
a substrate;
a reflective electrode layer disposed on the substrate;
a light-emitting element layer disposed on the reflective electrode layer; and
a pattern layer disposed on the light-emitting element layer, and configured to transmit a first portion of light to the outside and to reflect a second portion of light back towards the reflective electrode layer,
wherein the reflective electrode layer includes a plurality of reflective electrode layer portions that are disposed at different depths with different distances from the pattern layer, and that are configured to reflect light back towards the pattern layer,
wherein each of the plurality of reflective electrode layer portions overlaps an emission area of a respective one of a plurality of sub-pixels.
